(19) United States
(12) Patent Application Publication
(10) Pub. No.: US 2026/0018563 A1
(43) Pub. Date: Jan. 15, 2026

(54) SEMICONDUCTOR PACKAGE AND MANUFACTURING METHOD THEREOF

(71) Applicant: SAMSUNG ELECTRONICS CO., LTD., Suwon-si (KR)

(72) Inventors: Jing Cheng LIN, Suwon-si (KR); Youngkun Jee, Suwon-si (KR)

(73) Assignee: SAMSUNG ELECTRONICS CO., LTD., Suwon-si (KR)

(21) Appl. No.: 19/027,965

(22) Filed: Jan. 17, 2025

(30) Foreign Application Priority Data
Jul. 12, 2024 (KR) 10-2024-0092586

(51) Int. Cl. H01L 25/065; H01L 21/56; H01L 23/00; H01L 23/31; H01L 23/538

(52) U.S. Cl. CPC H01L 25/0657; H01L 21/56; H01L 23/3121; H01L 23/5386; H01L 24/11; H01L 24/13; H01L 24/14; H01L 24/16; H01L 24/29; H01L 24/32; H01L 24/73; H01L 2224/11462; H01L 2224/11622; H01L 2224/13005; H01L 2224/13082; H01L 2224/13083; H01L 2224/1403; H01L 2224/16225; H01L 2224/29005; H01L 2224/32145; H01L 2224/32225; H01L 2224/73253; H01L 2225/06517; H01L 2225/06562; H01L 2924/1815

(57) ABSTRACT

Provided is a semiconductor package including a first semiconductor chip; a plurality of lower first conductive posts on the first semiconductor chip; a second semiconductor chip offset-stacked on the first semiconductor chip; a plurality of lower second conductive posts on the second semiconductor chip; a first molding layer around the first semiconductor chip, and the second semiconductor chip; a third adhesive layer on an upper surface of the first molding layer; a plurality of upper first conductive posts on the plurality of lower first conductive posts; a plurality of upper second conductive posts on the plurality of lower second conductive posts; a third semiconductor chip on the third adhesive layer; a plurality of third conductive posts on the third semiconductor chip; a second molding layer on the third adhesive layer; and a redistribution structure on the second molding layer.

### CROSS-REFERENCE TO RELATED APPLICATION

This application is based on and claims priority under 35 U.S.C. § 119 to Korean Patent Application No. 10-2024-0092586, filed on Jul. 12, 2024, in the Korean Intellectual Property Office, the disclosure of which is incorporated by reference herein in its entirety.

### BACKGROUND

The present disclosure relates to a semiconductor package, and more specifically, to a semiconductor package including a plurality of stacked semiconductor chips and a method of manufacturing the same.

With the recent rapid development of the electronics industry and the demands of users, electronic devices are becoming miniaturized, more multifunctional, and larger in capacity, and highly integrated semiconductor chips are being demanded. Accordingly, semiconductor packages that include highly integrated semiconductor chips with an increased number of input/output (I/O) connection terminals and that ensure connection reliability are being designed.

### SUMMARY

Embodiments of the disclosure provides a semiconductor package which may have excellent seed layer quality and a manufacturing method thereof.

In addition, the problems to be solved by the technical spirit of the present disclosure are not limited to the problems mentioned above, and other problems not mentioned will be clearly understood by those skilled in the art from the following description.

According to an aspect of an embodiment, a semiconductor package may include: a first semiconductor chip; a plurality of lower first conductive posts on the first semiconductor chip; a second semiconductor chip offset-stacked on the first semiconductor chip to be horizontally offset from the first semiconductor chip and horizontally spaced apart from the plurality of lower first conductive posts; a second adhesive layer on a lower surface of the second semiconductor chip; a plurality of lower second conductive posts on the second semiconductor chip; a first molding layer around the first semiconductor chip, the plurality of lower first conductive posts, the second semiconductor chip, and the plurality of lower second conductive posts; a third adhesive layer on an upper surface of the first molding layer; a plurality of upper first conductive posts on the plurality of lower first conductive posts and penetrating the third adhesive layer; a plurality of upper second conductive posts on the plurality of lower second conductive posts and penetrating the third adhesive layer; a third semiconductor chip on the third adhesive layer and horizontally spaced apart from the plurality of upper first conductive posts and the plurality of upper second conductive posts; a plurality of third conductive posts on the third semiconductor chip; a second molding layer on the third adhesive layer, the second molding layer being disposed around the plurality of upper first conductive posts, the plurality of upper second conductive posts, the plurality of third conductive posts, and the third semiconductor chip; and a redistribution structure on the second molding layer and in contact with the plurality of upper first conductive posts, the plurality of upper second conductive posts, and the plurality of third conductive posts.

According to an aspect of an embodiment, a semiconductor package may include: a first semiconductor chip; a second semiconductor chip offset-stacked on the first semiconductor chip to be horizontally offset from the first semiconductor ship; a second adhesive layer on a lower surface of the second semiconductor chip; a first molding layer on the first semiconductor chip, the second semiconductor chip, and the second adhesive layer; a third adhesive layer on an upper surface of the first molding layer; a third semiconductor chip on the third adhesive layer and horizontally offset from the second semiconductor chip; a second molding layer on the third adhesive layer and the third semiconductor chip; a fourth adhesive layer on the second molding layer; a fourth semiconductor chip on the fourth adhesive layer and horizontally offset from the third semiconductor chip; a third molding layer on the fourth adhesive layer and the fourth semiconductor chip; a redistribution structure on the third molding layer; a plurality of first conductive posts extending from the first semiconductor chip to the redistribution structure and horizontally spaced apart from the second semiconductor chip, the third semiconductor chip, and the fourth semiconductor chip; a plurality of second conductive posts extending from the second semiconductor chip to the redistribution structure and horizontally spaced apart from the third semiconductor chip and the fourth semiconductor chip; a plurality of third conductive posts extending from the third semiconductor chip to the redistribution structure and horizontally spaced apart from the fourth semiconductor chip; and a plurality of fourth conductive posts extending from the fourth semiconductor chip to the redistribution structure.

According to an aspect of an embodiment, a method of manufacturing a semiconductor package, may include: disposing a first semiconductor chip on a first adhesive layer after applying the first adhesive layer on a carrier substrate; forming a plurality of lower first conductive posts on the first semiconductor chip; offset-stacking a second semiconductor chip on the first semiconductor chip to be horizontally offset from the first semiconductor chip and horizontally spaced apart from the plurality of lower first conductive posts, wherein the second semiconductor chip includes a plurality of lower second conductive posts on an upper surface thereof; forming a first molding layer on the first adhesive layer, the plurality of lower first conductive posts, the plurality of lower second conductive posts, and the second semiconductor chip; disposing a third semiconductor chip on a third adhesive layer after applying the third adhesive layer on the first molding layer, the third semiconductor chip including a plurality of third conductive posts on an upper surface thereof; forming a plurality of upper first conductive posts on the plurality of lower first conductive posts and a plurality of upper second conductive posts on the plurality of lower second conductive posts; forming a second molding layer on the third adhesive layer, the plurality of upper first conductive posts, the plurality of upper second conductive posts, the plurality of third conductive posts, and the third semiconductor chip; and forming a redistribution structure on the second molding layer.

### BRIEF DESCRIPTION OF THE DRAWINGS

Embodiments will be more clearly understood from the following detailed description taken in conjunction with the accompanying drawings, in which:

FIG. 1 is a schematic cross-sectional view showing a semiconductor package according to one or more embodiments;

FIG. 2 is a schematic cross-sectional view showing a semiconductor package according to one or more embodiments;

FIG. 3 is a schematic cross-sectional view showing a semiconductor package according to one or more embodiments;

FIG. 4 is a schematic cross-sectional view showing a semiconductor package according to one or more embodiments;

FIG. 5 is a schematic enlarged view showing a portion “EX” of the semiconductor package of FIG. 4;

FIG. 6 is a schematic enlarged view showing a portion of a semiconductor package according to one or more embodiments;

FIG. 7 is a schematic cross-sectional view showing a semiconductor package according to one or more embodiments;

FIG. 8 is a schematic cross-sectional view showing a semiconductor package according to one or more embodiments;

FIG. 9A is a diagram illustrating a method of manufacturing a semiconductor package according to one or more embodiments in accordance with the process sequence;

FIG. 9B is a diagram illustrating a method of manufacturing a semiconductor package according to one or more embodiments in accordance with the process sequence;

FIG. 9C is a diagram illustrating a method of manufacturing a semiconductor package according to one or more embodiments in accordance with the process sequence;

FIG. 9D is a diagram illustrating a method of manufacturing a semiconductor package according to one or more embodiments in accordance with the process sequence;

FIG. 9E is a diagram illustrating a method of manufacturing a semiconductor package according to one or more embodiments in accordance with the process sequence;

FIG. 9F is a diagram illustrating a method of manufacturing a semiconductor package according to one or more embodiments in accordance with the process sequence;

FIG. 9G is a diagram illustrating a method of manufacturing a semiconductor package according to one or more embodiments in accordance with the process sequence;

FIG. 9H is a diagram illustrating a method of manufacturing a semiconductor package according to one or more embodiments in accordance with the process sequence;

FIG. 9I is a diagram illustrating a method of manufacturing a semiconductor package according to one or more embodiments in accordance with the process sequence;

FIG. 9J is a diagram illustrating a method of manufacturing a semiconductor package according to one or more embodiments in accordance with the process sequence;

FIG. 9K is a diagram illustrating a method of manufacturing a semiconductor package according to one or more embodiments in accordance with the process sequence;

FIG. 9L is a diagram illustrating a method of manufacturing a semiconductor package according to one or more embodiments in accordance with the process sequence;

FIG. 9M is a diagram illustrating a method of manufacturing a semiconductor package according to one or more embodiments in accordance with the process sequence;

FIG. 9N is a diagram illustrating a method of manufacturing a semiconductor package according to one or more embodiments in accordance with the process sequence;

FIG. 9O is a diagram illustrating a method of manufacturing a semiconductor package according to one or more embodiments in accordance with the process sequence;

FIG. 9P is a diagram illustrating a method of manufacturing a semiconductor package according to one or more embodiments in accordance with the process sequence;

FIG. 9Q is a diagram illustrating a method of manufacturing a semiconductor package according to one or more embodiments in accordance with the process sequence;

FIG. 9R is a diagram illustrating a method of manufacturing a semiconductor package according to one or more embodiments in accordance with the process sequence;

FIG. 9S is a diagram illustrating a method of manufacturing a semiconductor package according to one or more embodiments in accordance with the process sequence; and

FIG. 9T is a diagram illustrating a method of manufacturing a semiconductor package according to one or more embodiments in accordance with the process sequence.

### DETAILED DESCRIPTION

The disclosure may be modified into various forms and may have various embodiments. In this regard, the disclosure will now be made in detail to embodiments, examples of which are illustrated in the accompanying drawings. However, this is not intended to limit the present embodiments to a specific disclosure form.

In the specification, spatially relative terms such as “top”, “bottom”, “upper”, “lower”, “up”, “down”, etc. are used to easily explain the positional relationship of each component when viewed from a direction depicted in the drawings. Therefore, spatially relative terms indicating the positional relationship of each component may be understood differently when viewed from a direction other than the direction depicted in the drawings.

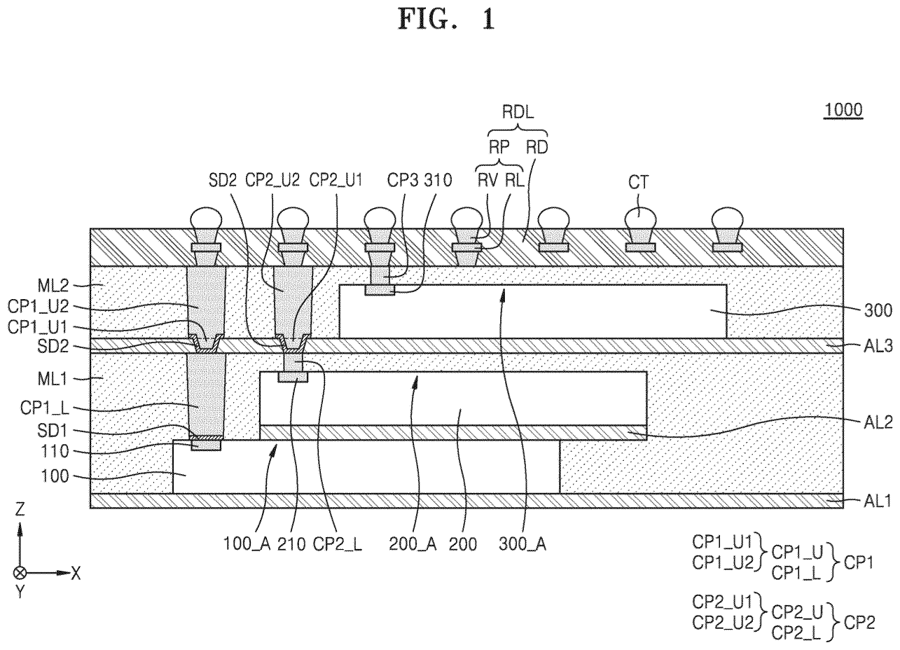

FIG. 1 is a schematic cross-sectional view showing a semiconductor package 1000 according to one or more embodiments.

Referring to FIG. 1, the semiconductor package 1000 may include a first semiconductor chip 100, a plurality of first conductive posts CP1, a first molding layer ML1, a second adhesive layer AL2, a second semiconductor chip 200, a plurality of second conductive posts CP2, a second molding layer ML2, a third adhesive layer AL3, a third semiconductor chip 300, a plurality of third conductive posts CP3, and a redistribution structure RDL.

For example, each of the plurality of first conductive posts CP1 may be divided into a lower first conductive post CP1_L and an upper first conductive post CP1_U. Each of the plurality of second conductive posts CP2 may be divided into a lower second conductive post CP2_L and an upper second conductive post CP2_U.

Hereinafter, unless otherwise specifically defined, a direction parallel to an upper surface of the first adhesive layer AL1 is defined as a first horizontal direction (X direction), a direction perpendicular to the upper surface of the first adhesive layer AL1 is defined as a vertical direction (Z direction), and a direction perpendicular to the first horizontal direction (X direction) and the vertical direction (Z direction) is defined as a second horizontal direction (Y direction). The horizontal direction is defined as a direction that combines the first horizontal direction (X direction) and the second horizontal direction (Y direction).

In some embodiments, the semiconductor package 1000 may further include a first adhesive layer AL1.

The first semiconductor chip 100 may be arranged on the first adhesive layer AL1. The upper surface of the first adhesive layer AL1 may have a greater area than the lower surface of the first semiconductor chip 100. In some embodiments, the first adhesive layer AL1 may be at least one of a non-conductive film (NCF) and a die attach film (DAF).

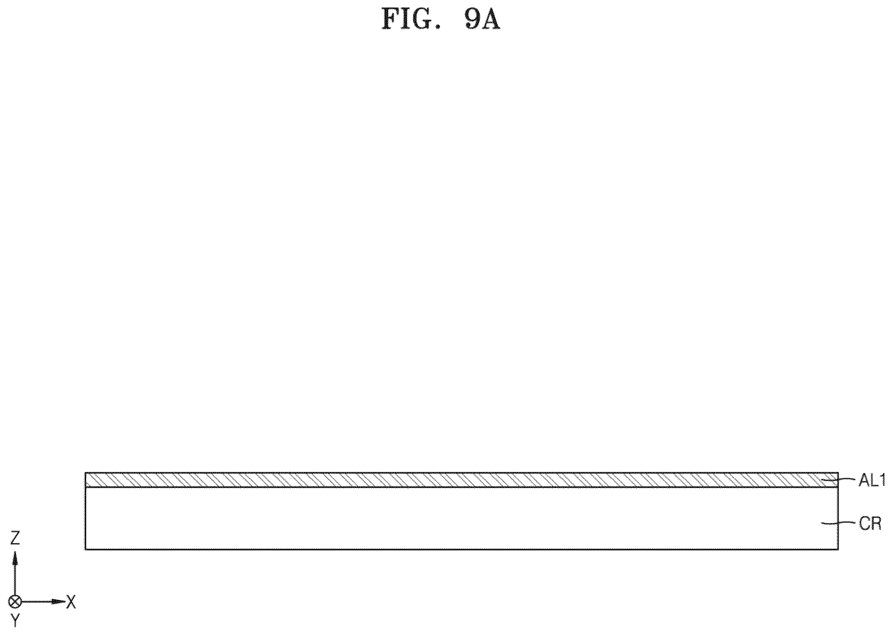

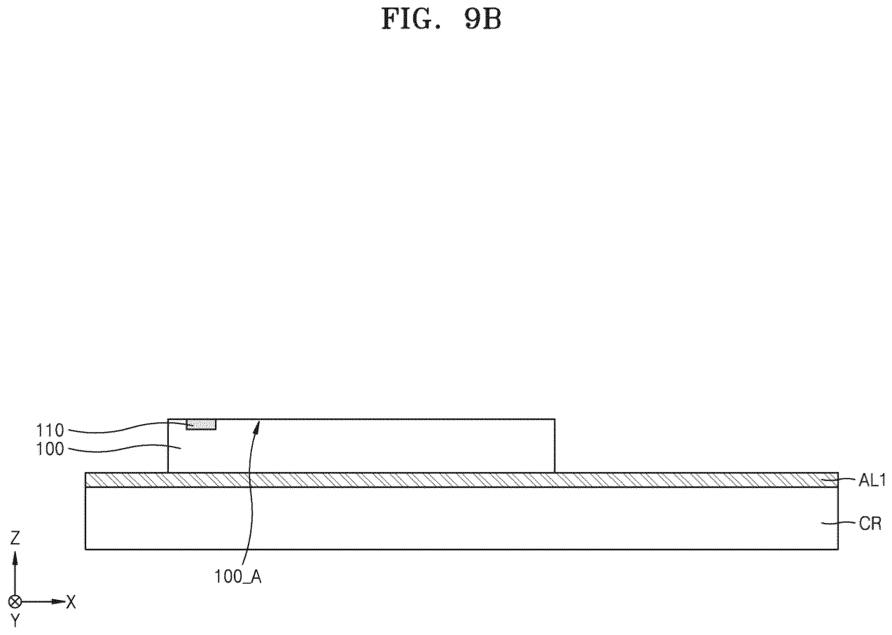

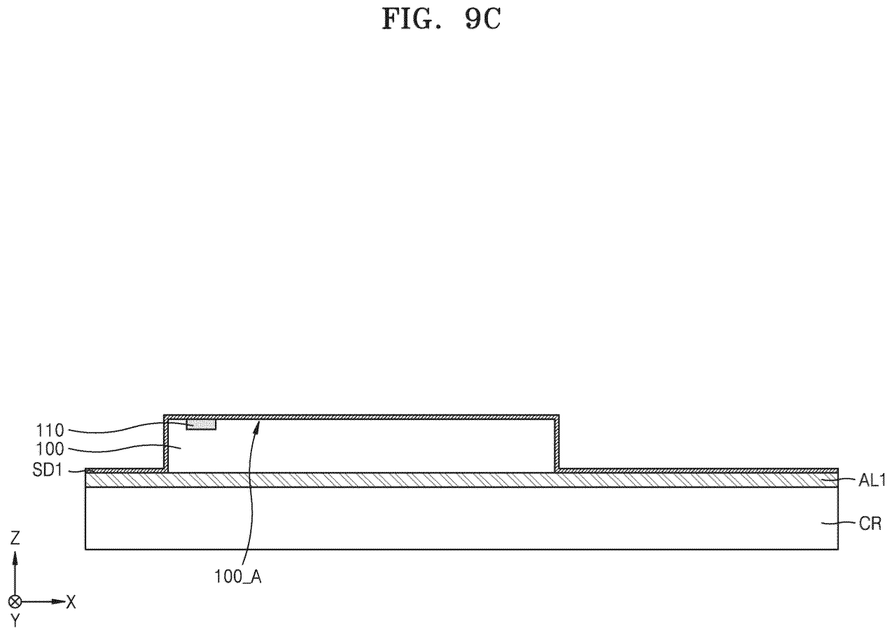

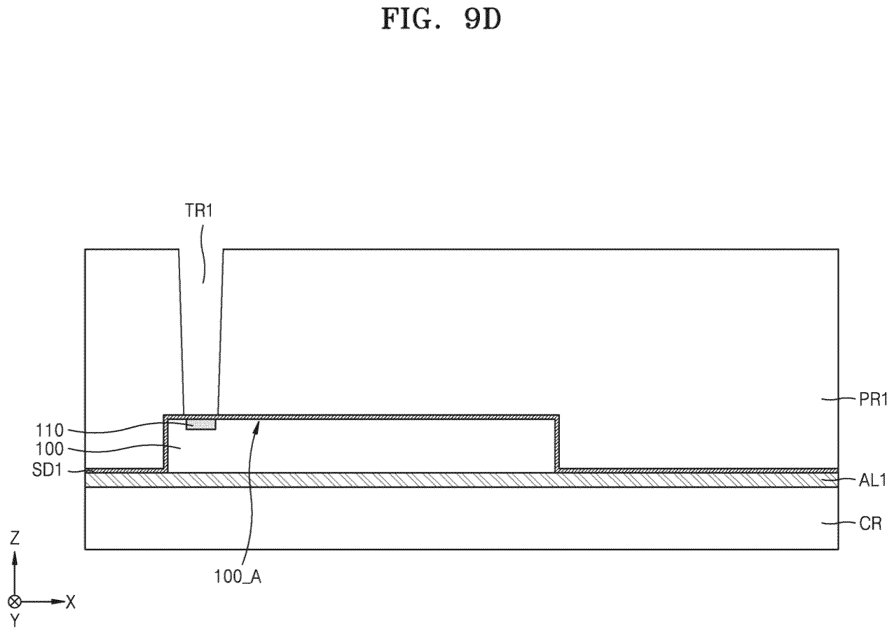

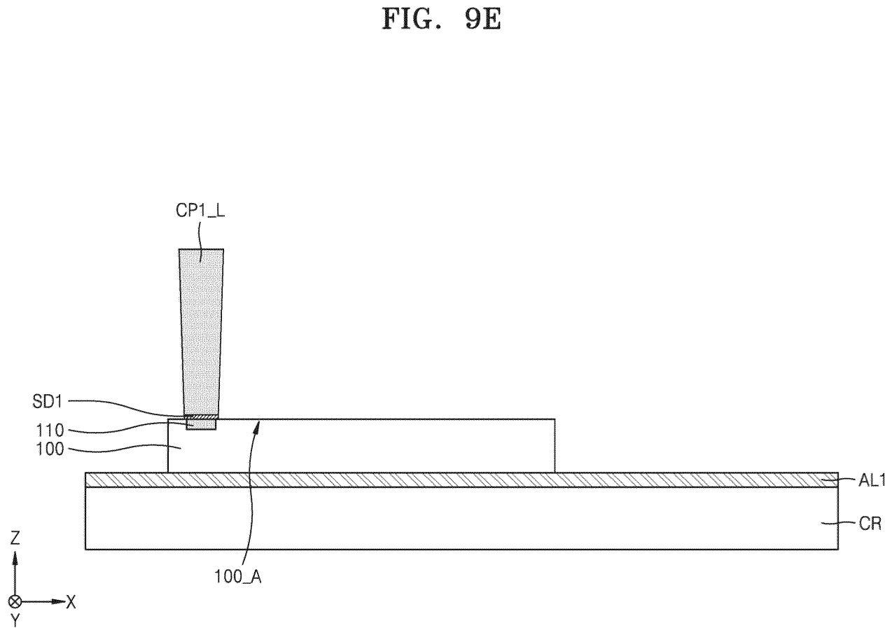

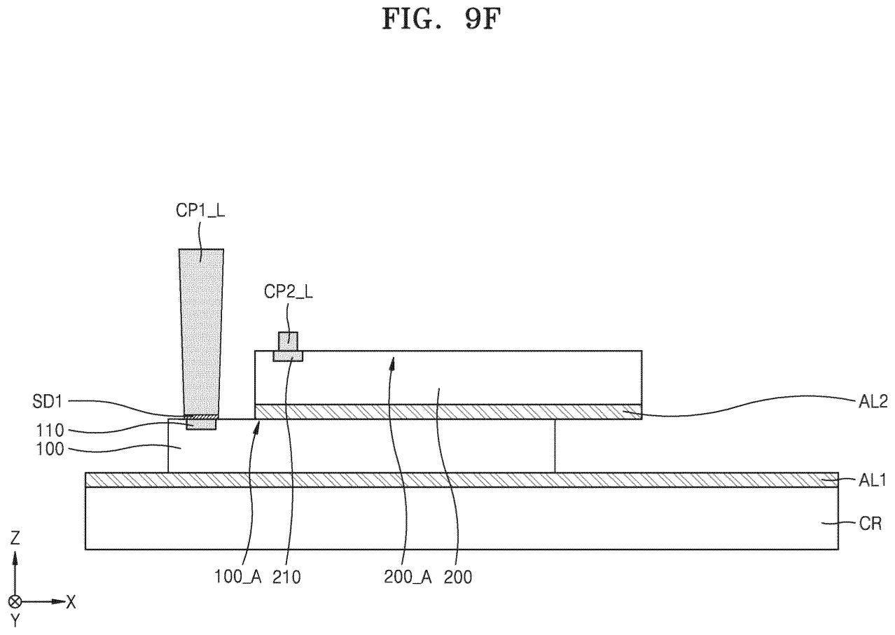

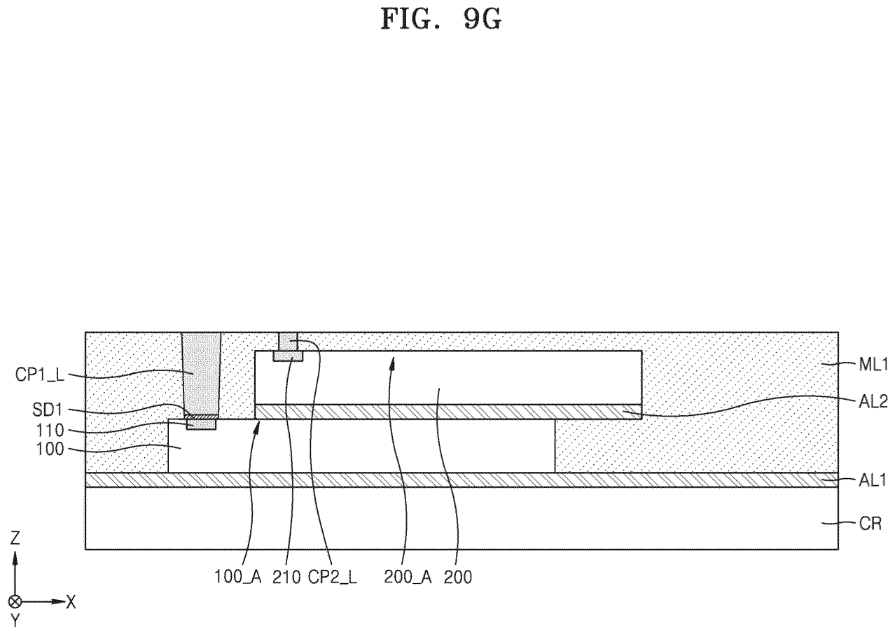

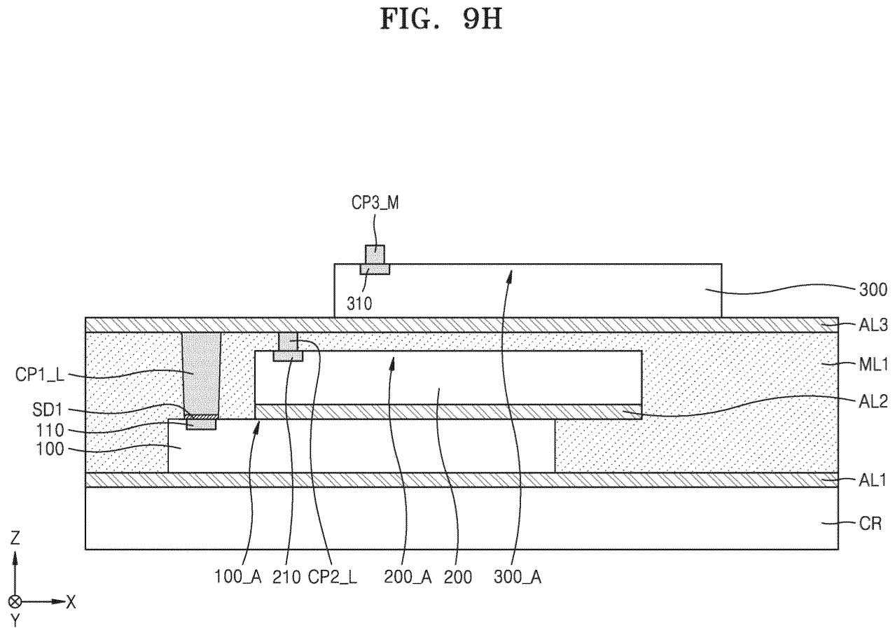

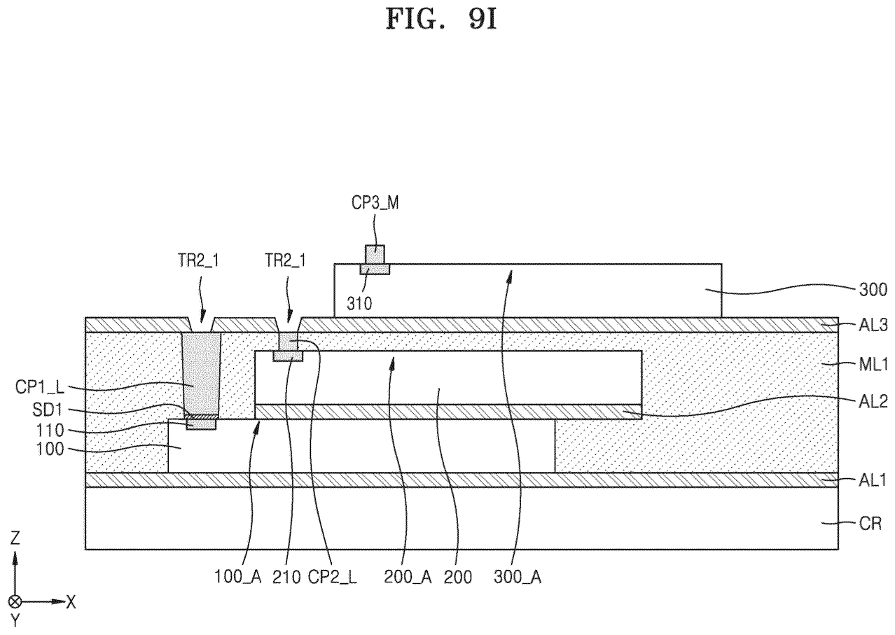

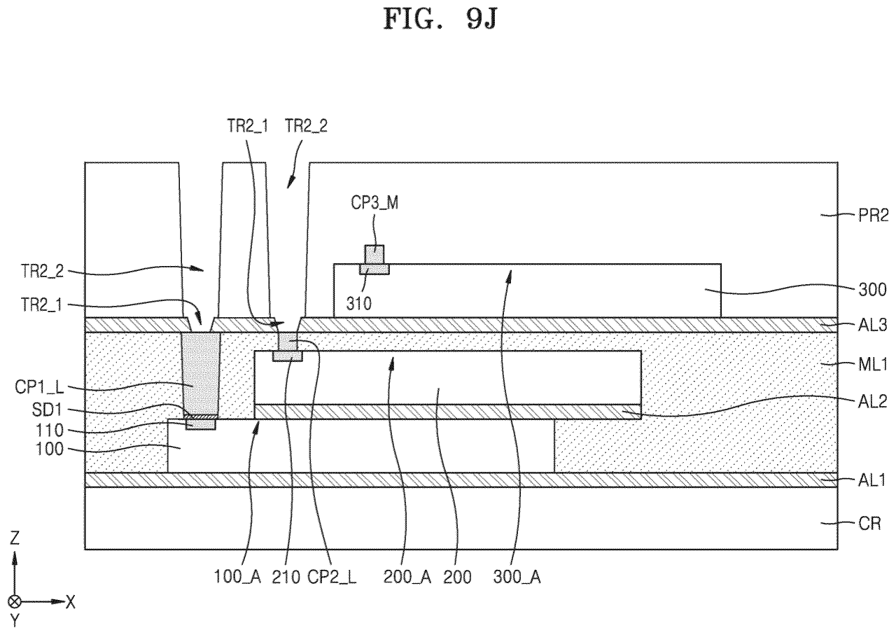

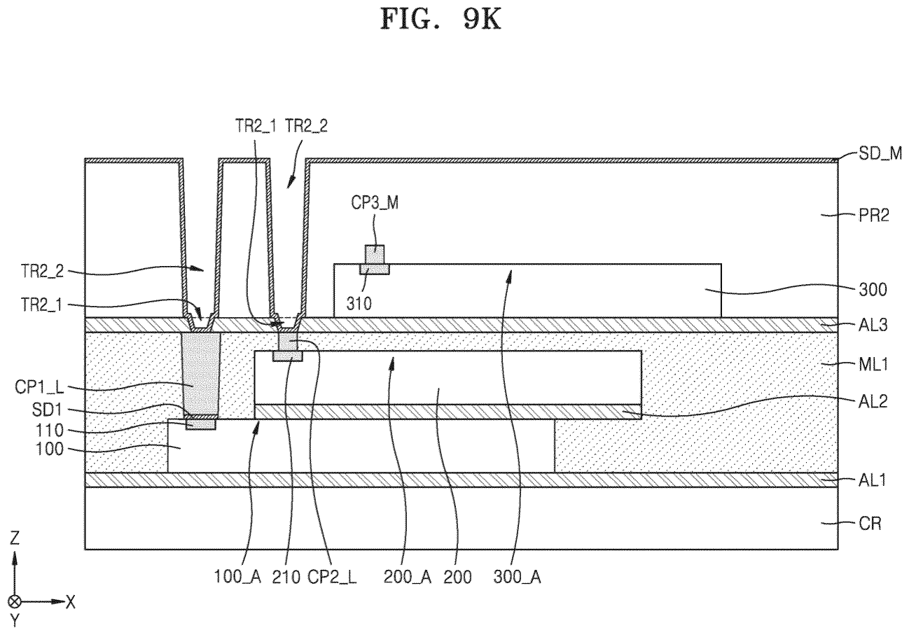

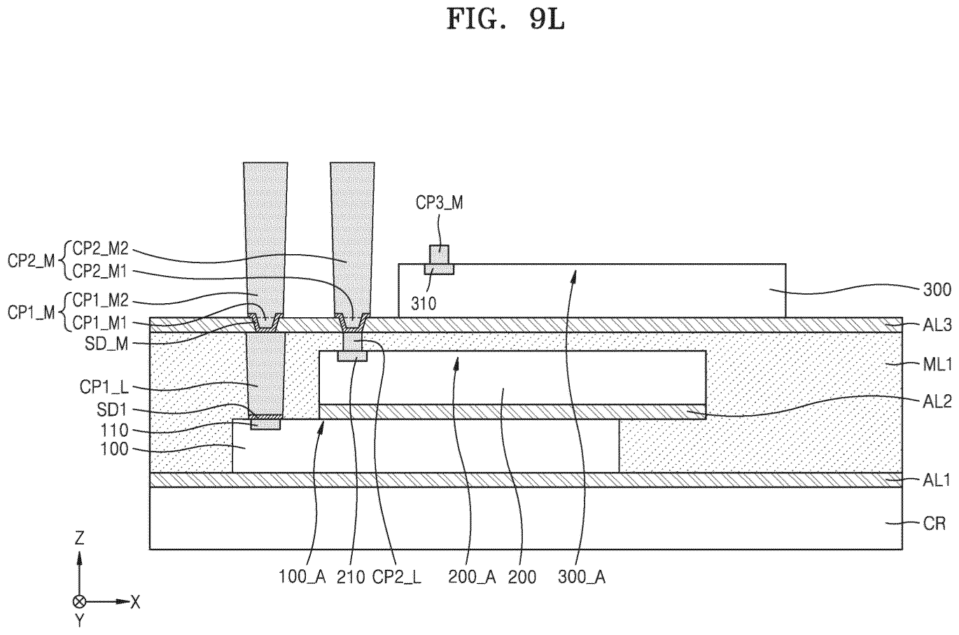

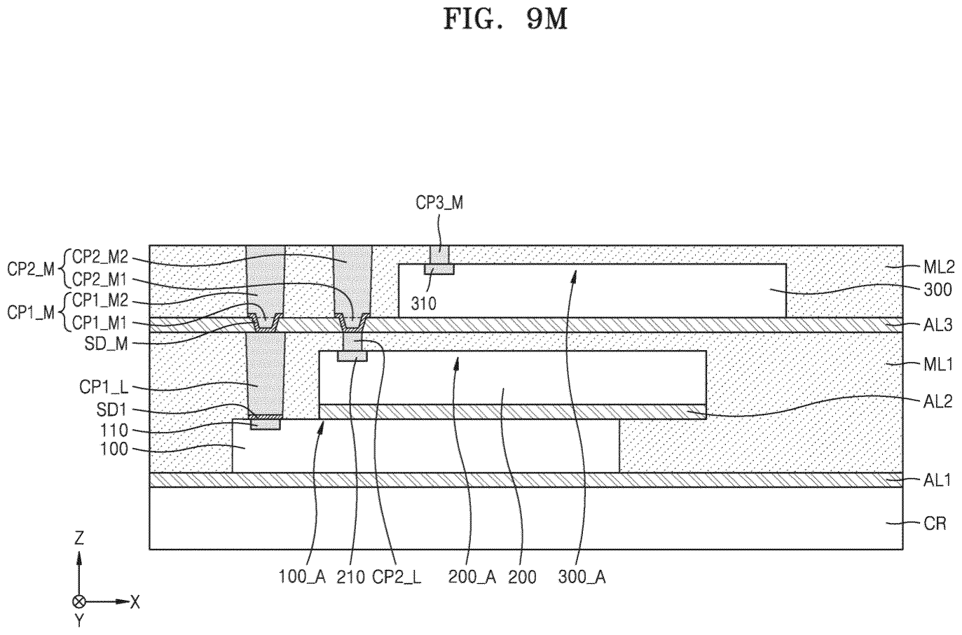

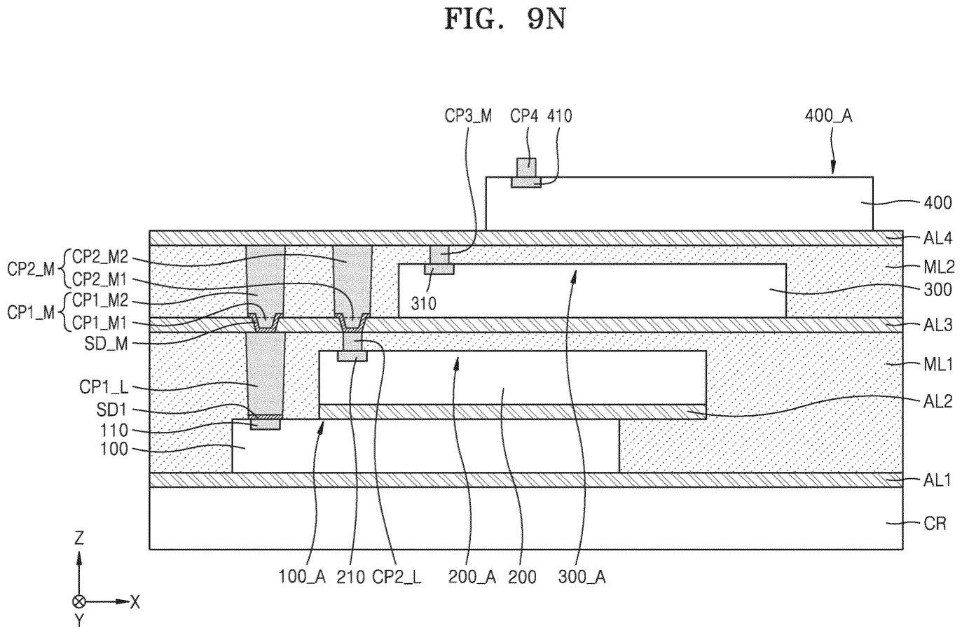

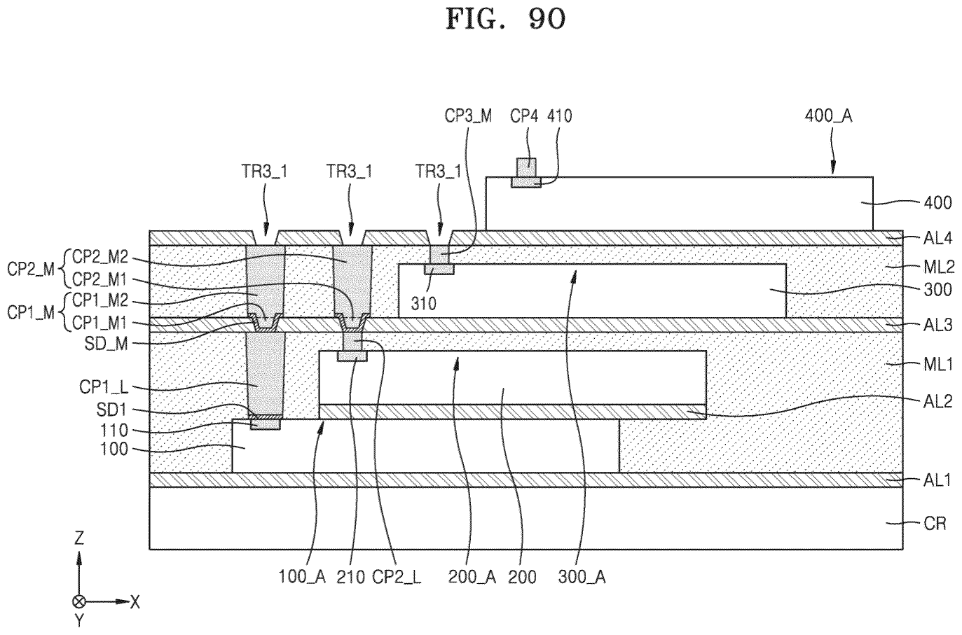

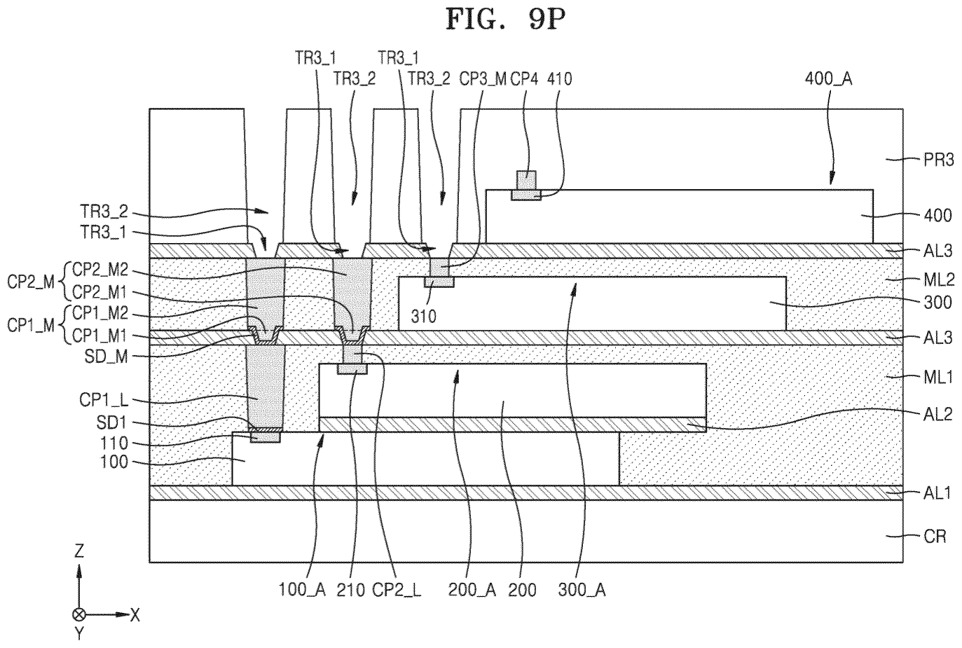

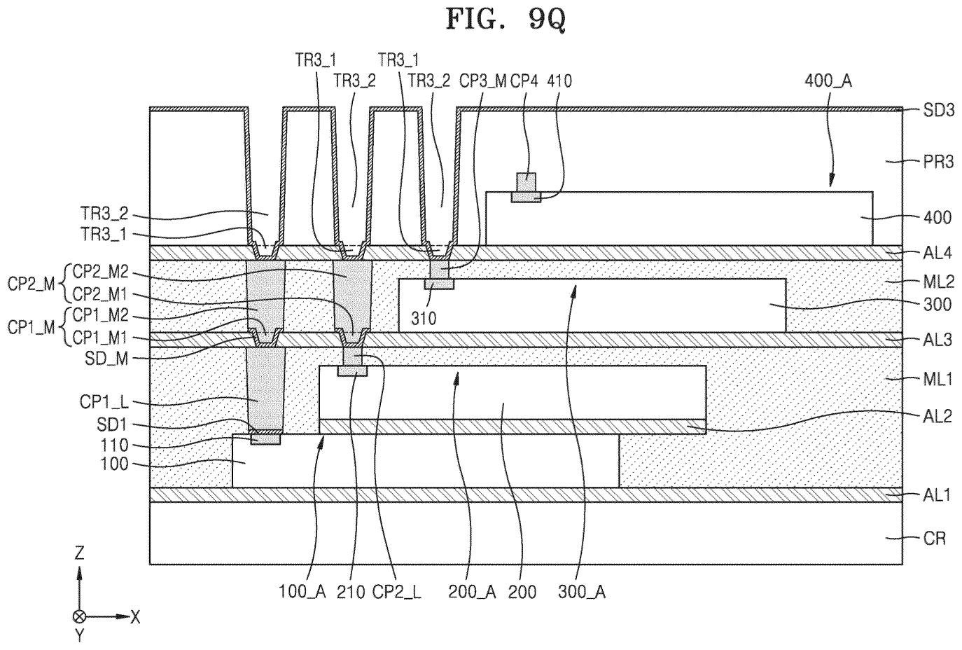

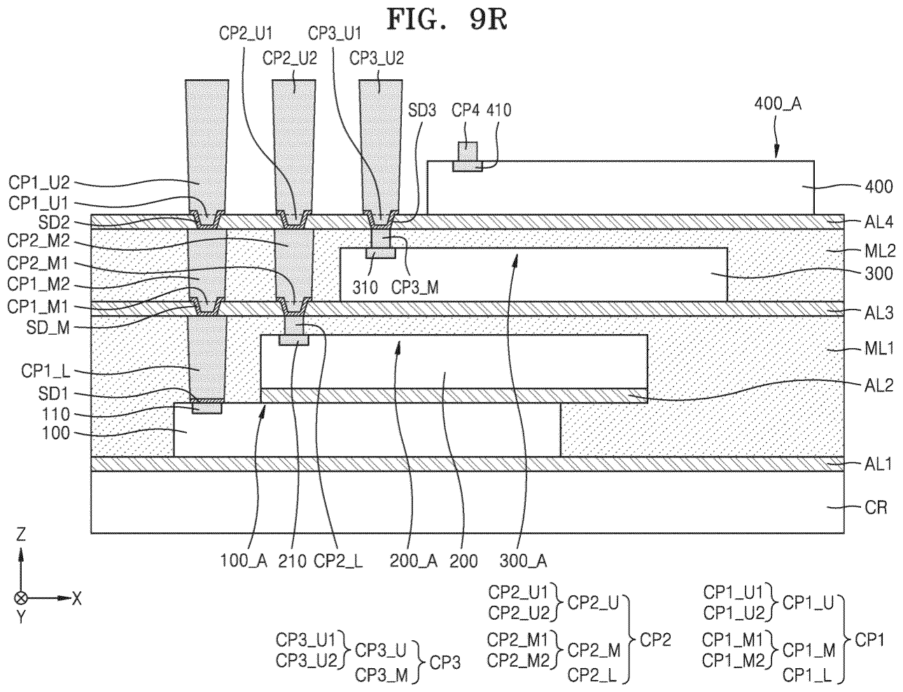

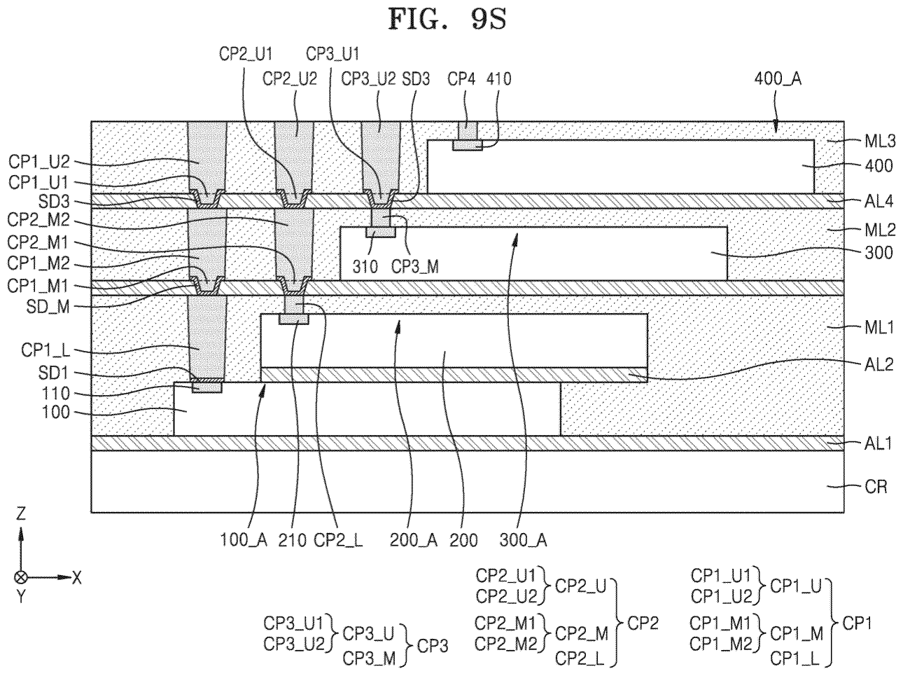

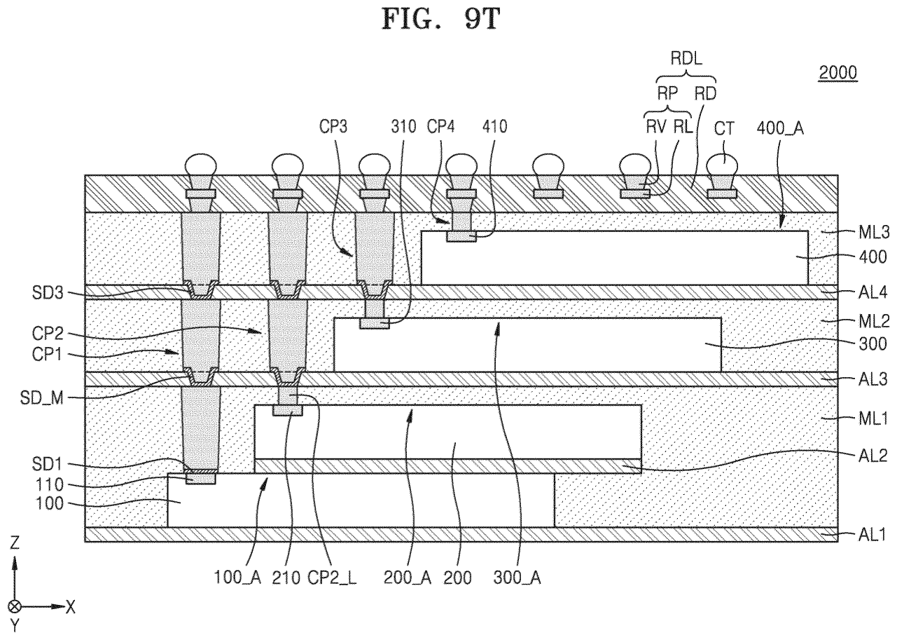

In some embodiments, after the first adhesive layer AL1 is applied to a carrier substrate CR (see FIG. 9A), the first semiconductor chip 100 may be arranged on the first adhesive layer AL1. An area on which the first adhesive layer AL1 is applied is greater than an area of the lower surface of the first semiconductor chip 100, and thus, in a process of attaching the first semiconductor chip 100 to the first adhesive layer AL1, a phenomenon of fillet generation at an edge of the lower surface of the first semiconductor chip 100 due to overflow of the first adhesive layer AL1 may be suppressed.

For example, an uneven upper surface of the first adhesive layer AL1 due to the attachment of the first semiconductor chip 100 on the coated first adhesive layer AL1 may be suppressed. Because the upper surface of the first adhesive layer AL1 is relatively flat, a phenomenon of peeling off the lower seed layer SD1 during a process of forming the lower seed layer SD1 may be suppressed.

The first semiconductor chip 100 may include an active surface 100_A and an inactive surface opposite thereto. In some embodiments, the first semiconductor chip 100 may be placed on the first adhesive layer AL1 so that the active surface 100_A of the first semiconductor chip 100 faces the redistribution structure RDL. For example, the first semiconductor chip 100 may be placed on the first adhesive layer AL1 so that the active surface 100_A of the first semiconductor chip 100 faces upward in the vertical direction (Z direction).

In some embodiments, the first semiconductor chip 100 may further include a plurality of first input/output terminals 110. The plurality of first input/output terminals 110 may be located on the active surface 100_A of the first semiconductor chip 100.

The plurality of lower first conductive posts CP1_L are located on the upper surface of the first semiconductor chip 100 and may extend in the vertical direction (Z direction). For example, the plurality of lower first conductive posts CP1_L may be respectively located at the plurality of first input/output terminals 110 of the first semiconductor chip 100.

In some embodiments, each of the plurality of lower first conductive posts CP1_L may have a less horizontal width toward the first semiconductor chip 100. For example, each of the plurality of lower first conductive posts CP1_L may have a less horizontal width downwards in the vertical direction (Z direction).

In some embodiments, the semiconductor package 1000 may further include the lower seed layer SD1. The lower seed layer SD1 may be located between the plurality of lower first conductive posts CP1_L and the first semiconductor chip 100. For example, the lower seed layer SD1 may be conformally formed on the first semiconductor chip 100. A side surface of the lower seed layer SD1 may be coplanar with a side surface of the plurality of lower first conductive posts CP1_L.

The second semiconductor chip 200 may be located on the first semiconductor chip 100. The second semiconductor chip 200 may be offset-stacked on the first semiconductor chip 100. The second semiconductor chip 200 may be horizontally spaced from the plurality of lower first conductive posts CP1_L. For example, the second semiconductor chip 200 may be offset-stacked on the first semiconductor chip 100 so that the plurality of first input/output terminals 110 of the first semiconductor chip 100 do not overlap with the second semiconductor chip 200.

In some embodiments, a second adhesive layer AL2 may be located on a lower surface of the second semiconductor chip 200. An area of an upper surface of the second adhesive layer AL2 may be equal to an area of the lower surface of the second semiconductor chip 200. For example, a portion of the lower surface of the second adhesive layer AL2 may be in contact with the first semiconductor chip 100, and the other portion of the lower surface of the second adhesive layer AL2 may be in contact with the first molding layer ML1. The second adhesive layer AL2 may be at least one of a NCF and a DAF.

The second semiconductor chip 200 may include an active surface 200_A and an inactive surface opposite thereto. In some embodiments, the second semiconductor chip 200 may be located on the first semiconductor chip 100 so that the active surface 200_A of the second semiconductor chip 200 faces the redistribution structure RDL. For example, the second semiconductor chip 200 may be offset-stacked so that the active surface 200_A of the second semiconductor chip 200 faces upward in the vertical direction (Z direction).

In some embodiments, the second semiconductor chip 200 may further include a plurality of second input/output terminals 210. The plurality of second input/output terminals 210 may be located on the active surface 200_A of the second semiconductor chip 200.

The plurality of lower second conductive posts CP2_L may be located on an upper surface of the second semiconductor chip 200 and may extend in the vertical direction (Z direction). For example, the plurality of lower second conductive posts CP2_L may be located on the plurality of second input/output terminals 210 of the second semiconductor chip 200, respectively. For example, each of the plurality of lower second conductive posts CP2_L may be referred to as a conductive pillar.

In some embodiments, a horizontal width of each of the plurality of lower second conductive posts CP2_L may be less than a horizontal width of each of the plurality of lower first conductive posts CP1_L. A length in the vertical direction (Z direction) of each of the plurality of lower second conductive posts CP2_L may be less than a length in the vertical direction (Z direction) of each of the plurality of lower first conductive posts CP1_L.

In some embodiments, the plurality of lower first conductive posts CP1_L may be formed after attaching the first semiconductor chip 100 on a carrier substrate CR (see FIG. 9A), and after forming a plurality of lower second conductive posts CP2_L on the second semiconductor chip 200 in a separate process, the second semiconductor chip 200 may be attached on the first semiconductor chip 100. Due to the difference in manufacturing processes of the plurality of lower first conductive posts CP1_L and the plurality of lower second conductive posts CP2_L, there may be a difference in the shape between the plurality of lower first conductive posts CP1_L and the plurality of lower second conductive posts CP2_L.

The first molding layer ML1 may surround the first semiconductor chip 100, the plurality of lower first conductive posts CP1_L, the second semiconductor chip 200, and the plurality of lower second conductive posts CP2_L. In some embodiments, the first molding layer ML1 may be located on the first adhesive layer AL1. For example, the second adhesive layer AL2 may be located inside the first molding layer ML1, and the first adhesive layer AL1 may be located under the first molding layer ML1.

In some embodiments, the upper surface of the first molding layer ML1, upper surfaces of the plurality of lower first conductive posts CP1_L, and upper surfaces of the plurality of lower second conductive posts CP2_L may be coplanar. In some embodiments, the first molding layer ML1 may include an epoxy resin or a polyimide resin, etc. The first molding layer ML1 may include, for example, an epoxy molding compound (EMC).

The third adhesive layer AL3 may be located on the first molding layer ML1. An area of an upper surface of the third adhesive layer AL3 may be greater than an area of a lower surface of the third semiconductor chip 300. In some embodiments, the third adhesive layer AL3 may be at least one of an NCF and a DAF.

A plurality of upper first conductive posts CP1_U may be located on a plurality of lower first conductive posts CP1_L. For example, the plurality of upper first conductive posts CP1_U may penetrate the third adhesive layer AL3 and contact the plurality of lower first conductive posts CP1_L. For example, a plurality of upper first conductive posts CP1_U and the plurality of lower first conductive posts CP1_L may correspond one-to-one. The upper first conductive posts CP1_U and the lower first conductive posts CP1_L may be collectively referred to as a first conductive post CP1. The plurality of first conductive posts CP1 may extend from the first semiconductor chip 100 to the redistribution structure RDL.

A plurality of upper second conductive posts CP2_U may be located on the plurality of lower second conductive posts CP2_L. For example, the plurality of upper second conductive posts CP2_U may penetrate the third adhesive layer AL3 and come into contact with the plurality of lower second conductive posts CP2_L. For example, the plurality of upper second conductive posts CP2_U and the plurality of lower second conductive posts CP2_L may correspond one-to-one. A combination of the upper second conductive posts CP2_U and the lower second conductive posts CP2_L may be referred to as a second conductive post CP2. The plurality of second conductive posts CP2 may extend from the second semiconductor chip 200 to the redistribution structure RDL.

The third semiconductor chip 300 may be located on the third adhesive layer AL3. The third semiconductor chip 300 may be horizontally spaced apart from the plurality of upper first conductive posts CP1_U and the plurality of upper second conductive posts CP2_U. For example, the third semiconductor chip 300 may be attached onto the third adhesive layer AL3 so that the plurality of lower first conductive posts CP1_L and the plurality of lower second conductive posts CP2_L do not overlap with the third semiconductor chip 300.

The third semiconductor chip 300 may include an active surface 300_A and an inactive surface opposite thereto. In some embodiments, the third semiconductor chip 300 may be placed on the third adhesive layer AL3 so that the active surface 300_A of the third semiconductor chip 300 faces the redistribution structure RDL. For example, the third semiconductor chip 300 may be located on the third adhesive layer AL3 so that the active surface 300_A of the third semiconductor chip 300 faces upward in the vertical direction (Z direction).

In some embodiments, the third semiconductor chip 300 may further include a plurality of third input/output terminals 310. The plurality of third input/output terminals 310 may be located on the active surface 300_A of the third semiconductor chip 300.

In some embodiments, a plurality of individual devices of various types may be located on the active surface 100_A of the first semiconductor chip 100, the active surface 200_A of the second semiconductor chip 200, and the active surface 300_A of the third semiconductor chip 300. The plurality of individual devices of each of the first semiconductor chip 100, the second semiconductor chip 200, and the third semiconductor chip 300 may be electrically connected to a wiring area of each of the first semiconductor chip 100, the second semiconductor chip 200, and the third semiconductor chip 300.

For example, the plurality of individual devices of each chip may include various micro electronic devices, such as a complementary metal-oxide semiconductor (CMOS) transistor, a metal-oxide-semiconductor field effect transistor (MOSFET), a system large scale integration (LSI), an image sensor such as a CMOS imaging sensor (CIS), a micro-electro-mechanical system (MEMS), an active element, a passive element, etc.

The plurality of third conductive posts CP3 are located on an upper surface of the third semiconductor chip 300 and may extend in the vertical direction (Z direction). For example, the plurality of third conductive posts CP3 may be respectively located at the plurality of third input/output terminals 310 of a third semiconductor chip 300. For example, each of the plurality of third conductive posts CP3 may be referred to as a conductive pillar.

In some embodiments, a horizontal width of each of the plurality of upper second conductive posts CP2_U and a horizontal width of each of the plurality of upper first conductive posts CP1_U may be greater than a horizontal width of each of the plurality of third conductive posts CP3. A length in the vertical direction (Z direction) of each of the plurality of upper first conductive posts CP1_U and a length in the vertical direction (Z direction) of each of the plurality of upper second conductive posts CP2_U may be greater than a length in the vertical direction (Z direction) of each of the plurality of third conductive posts CP3.

The second molding layer ML2 may be located on the third adhesive layer AL3. The second molding layer ML2 may surround the plurality of upper first conductive posts CP1_U, the plurality of upper second conductive posts CP2_U, the third semiconductor chip 300, and the plurality of third conductive posts CP3.

In some embodiments, an upper surface of the second molding layer ML2, upper surfaces of the plurality of upper first conductive posts CP1_U, upper surfaces of the plurality of upper second conductive posts CP2_U, and upper surfaces of the plurality of third conductive posts CP3 may be coplanar. In some embodiments, the second molding layer ML2 may include an epoxy resin or a polyimide resin. The second molding layer ML2 may include, for example, an EMC.

The plurality of upper first conductive posts CP1_U may be surrounded by the third adhesive layer AL3 and the second molding layer ML2. For example, a plurality of upper first conductive posts CP1_U may penetrate the third adhesive layer AL3 and the second molding layer ML2 and contact a plurality of lower first conductive posts CP1_L and the redistribution structure RDL.

Each of the plurality of upper first conductive posts CP1_U may be divided into a first portion CP1_U1 and a second portion CP1_U2. The first portion CP1_U1 of each of the plurality of upper first conductive posts CP1_U may be a portion surrounded by the third adhesive layer AL3 among the plurality of upper first conductive posts CP1_U, and the second portion CP1_U2 of each of the plurality of upper first conductive posts CP1_U may be a portion surrounded by the second molding layer ML2 among the plurality of upper first conductive posts CP1_U.

In some embodiments, a horizontal width of the upper first conductive post CP1_U at the first portion CP1_U1 and a horizontal width of the upper first conductive post CP1_U at the second portion CP1_U2 may be different from each other. For example, a portion of the first portion CP1_U1 of the upper first conductive post CP1_U may be in contact with the upper surface of the third adhesive layer AL3.

The plurality of upper second conductive posts CP2_U may be surrounded by the third adhesive layer AL3 and the second molding layer ML2. For example, each of the plurality of upper second conductive posts CP2_U may penetrate the third adhesive layer AL3 and the second molding layer ML2 and be in contact with the plurality of lower second conductive posts CP2_L and the redistribution structure RDL.

Each of the plurality of upper second conductive posts CP2_U may be divided into a first portion CP2_U1 and a second portion CP2_U2. The first portion CP2_U1 of each of the plurality of upper second conductive posts CP2_U may be a portion surrounded by the third adhesive layer AL3 among the plurality of upper second conductive posts CP2_U, and the second portion CP2_U2 of each of the plurality of upper second conductive posts CP2_U may be a portion surrounded by the second molding layer ML2 among the plurality of upper second conductive posts CP2_U.

In some embodiments, a horizontal width of the upper second conductive post CP2_U at the first portion CP2_U1 and a horizontal width of the upper second conductive post CP2_U at the second portion CP2_U2 may be different from each other. For example, a portion of the first portion CP2_U1 of the upper second conductive post CP2_U may be in contact with the upper surface of the third adhesive layer AL3.

In some embodiments, each of the plurality of upper second conductive posts CP2_U may have a horizontal width that decreases downwards in the vertical direction. Each of the plurality of upper second conductive posts CP2_U may have a smaller horizontal width towards the first molding layer ML1. For example, a horizontal width of a lower surface of the second portion CP2_U2 of the upper first conductive post CP1_U may be less than the upper surface of the lower first conductive post CP1_L.

For example, as illustrated in FIG. 1, a horizontal width of the upper first conductive post CP1_U at the first portion CP1_U1 may be greater than a horizontal width of the upper first conductive post CP1_U at the second portion CP1_U2. The horizontal width of the upper second conductive post CP2_U at the first portion CP2_U1 may be greater than the horizontal width of the upper first conductive post CP1_U in the second portion CP2_U2.

In some embodiments, each of the plurality of upper first conductive posts CP1_U and the plurality of upper second conductive posts CP2_U may have a horizontal width that decreases downwards in the vertical direction (Z direction). Each of the plurality of upper first conductive posts CP1_U and the plurality of upper second conductive posts CP2_U may have a horizontal width that decreases towards the first molding layer ML1. For example, a horizontal width of a lower surface of the second portion CP1_U2 of the upper first conductive post CP1_U may be less than the upper surface of the lower first conductive post CP1_L. For example, the horizontal width of a lower surface of the second portion CP2_U2 of the upper second conductive post CP2_U may be less than the upper surface of the lower second conductive post CP2_L.

In some embodiments, the semiconductor package 1000 may further include an upper seed layer SD2. A portion of the upper seed layer SD2 may be located between the plurality of upper first conductive posts CP1_U and the third adhesive layer AL3, and between the plurality of upper first conductive posts CP1_U and the plurality of lower first conductive posts CP1_L. The upper seed layer SD2 may be located between the plurality of upper second conductive posts CP2_U and the third adhesive layer AL3, and between the plurality of upper second conductive posts CP2_U and the plurality of lower second conductive posts CP2_L. For example, the upper seed layer SD2 may be located on the side and bottom surface of the second portion CP1_U2 of the plurality of upper first conductive posts CP1_U, and on the side and bottom surface of the second portion CP2_U2 of the plurality of upper second conductive posts CP2_U.

The redistribution structure RDL may be located on the second molding layer ML2. The redistribution structure RDL may be in contact with the plurality of upper first conductive posts CP1_U, the plurality of upper second conductive posts CP2_U, and the plurality of third conductive posts CP3.

The redistribution structure RDL may include a redistribution pattern RP and a redistribution insulating layer RD surrounding the redistribution pattern RP. The redistribution structure RDL may be electrically connected to each of the first semiconductor chip 100, the second semiconductor chip 200, and the third semiconductor chip 300. For example, the redistribution structure RDL may extend a plurality of first input/output terminals 110 of the first semiconductor chip 100 to the outside of the first semiconductor chip 100 and may extend a plurality of second input/output terminals 210 of the second semiconductor chip 200 to the outside of the second semiconductor chip 200.

The redistribution pattern RP may include a redistribution line RL extending in the horizontal direction and a redistribution via RV extending in the vertical direction (Z direction) from the redistribution line RL. The redistribution line RL may be arranged on at least one of upper and lower surfaces of the redistribution insulation layer RD or inside the redistribution insulation layer RD. The redistribution via RV may penetrate the redistribution insulation layer RD and be connected to some of the redistribution lines RL.

In some embodiments, a width of the redistribution via RV of the redistribution pattern RP may decrease towards a lower surface of the redistribution structure RDL. For example, the width of the redistribution via RV of the redistribution pattern RP may decrease towards the lower surface of the redistribution structure RDL. For example, the width of the redistribution via RV of the redistribution pattern RP may decrease towards the second molding layer ML2.

The redistribution via RV may be completely filled with a conductive material or may have a shape in which the conductive material is formed along a wall of the redistribution via RV. The redistribution pattern RP may include a conductive material, such as copper (Cu), aluminum (Al), silver (Ag), tin (Sn), gold (Au), nickel (Ni), lead (Pb), titanium (Ti), or an alloy thereof. The number and arrangement of the redistribution via RV and the redistribution line RL are not limited to those illustrated in the drawings and may vary according to the embodiments.

The redistribution insulation layer RD may include an insulating material, such as a photo-imageable dielectric (PID) resin. In this case, the redistribution insulation layer RD may further include an inorganic filler. In some embodiments, the redistribution insulation layer RD may have a multilayer structure in which the redistribution pattern RP is arranged in each layer.

In some embodiments, an external connection terminal CT may be attached to an upper surface of the redistribution structure RDL. The external connection terminal CT may be configured to electrically and physically connect between the redistribution structure RDL and an external device on which the redistribution structure RDL is mounted. The external connection terminal CT may be formed from, for example, a solder ball or a solder bump.

In some embodiments, a side surface of the first adhesive layer AL1, a side surface of the first molding layer ML1, a side surface of the third adhesive layer AL3, and a side surface of the second molding layer ML2 may be coplanar with each other. For example, the side surface of the first adhesive layer AL1 and the side surface of the third adhesive layer AL3 may be exposed to the outside of the semiconductor package 1000. For example, a side surface of the redistribution structure RDL may be coplanar with the side surface of the second molding layer ML2.

In some embodiments, a thickness of the first adhesive layer AL1 in the vertical direction (Z direction), a thickness of the second adhesive layer AL2 in the vertical direction (Z direction), and a thickness of the third adhesive layer AL3 in the vertical direction (Z direction) may each be in a range from about 5 μm to about 40 μm. For example, the thickness of the first adhesive layer AL1 in the vertical direction (Z direction), the thickness of the second adhesive layer AL2 in the vertical direction (Z direction), and the thickness of the third adhesive layer AL3 in the vertical direction (Z direction) may be different from each other.

In some embodiments, the area of the upper surface of the first adhesive layer AL1 may be greater than the area of the lower surface of the first semiconductor chip 100. The area of the upper surface of the second adhesive layer AL2 may be equal to the area of the lower surface of the second semiconductor chip 200. The area of the upper surface of the third adhesive layer AL3 may be greater than the area of the lower surface of the third semiconductor chip 300.

In some embodiments, the plurality of first conductive posts CP1, the plurality of second conductive posts CP2, and the plurality of third conductive posts CP3 may include a conductive material, for example, copper (Cu), aluminum (Al), silver (Ag), tin (Sn), gold (Au), nickel (Ni), lead (Pb), titanium (Ti), or an alloy thereof.

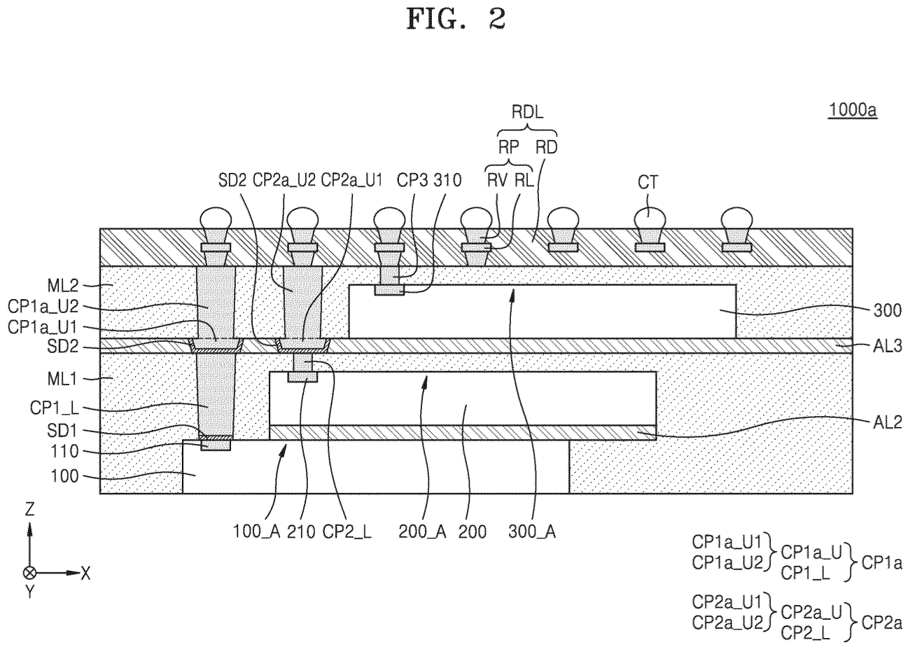

FIG. 2 is a schematic cross-sectional view showing a semiconductor package 1000a according to one embodiment.

Most of the components constituting the semiconductor package 1000a described below and the materials constituting the components are substantially the same as or similar to those described above with reference to FIG. 1. Therefore, for convenience of explanation, the difference between the semiconductor package 1000a of FIG. 2 and the semiconductor package 1000 of FIG. 1 described above is mainly explained.

Referring to FIG. 2, the semiconductor package 1000a may include a first semiconductor chip 100, a plurality of first conductive posts CP1a, a first molding layer ML1, a second adhesive layer AL2, a second semiconductor chip 200, a plurality of second conductive posts CP2a, a second molding layer ML2, a third adhesive layer AL3, a third semiconductor chip 300, a plurality of third conductive posts CP3, and a redistribution structure RDL.

In some embodiments, the semiconductor package 1000a may not include the first adhesive layer AL1 (see FIG. 1) of the semiconductor package 1000 of FIG. 1. The first adhesive layer AL1 (see FIG. 1) may be removed through a polishing process or the like after the first semiconductor chip 100 is removed from the carrier substrate CR (see FIG. 9A). Accordingly, the lower surfaces of the first semiconductor chip 100 and the first molding layer ML1 may be exposed to the outside. The lower surface of the first semiconductor chip 100 and the lower surface of the first molding layer ML1 may be coplanar.

The plurality of first conductive posts CP1a may extend in a vertical direction (Z direction) from the first semiconductor chip 100 to the redistribution structure RDL. For example, the plurality of first conductive posts CP1a may penetrate the first molding layer ML1, the third adhesive layer AL3, and the second molding layer ML2. For example, the plurality of first conductive posts CP1a may be in contact with the plurality of first input/output terminals 110 of the first semiconductor chip 100 and the redistribution pattern RP of the redistribution structure RDL. The plurality of first conductive posts CP1a may electrically connect the first semiconductor chip 100 to the redistribution structure RDL.

The plurality of first conductive posts CP1a may include a plurality of lower first conductive posts CP1_L and the plurality of upper first conductive posts CP1a_U. The plurality of lower first conductive posts CP1_L may be portions of the plurality of first conductive posts CP1a that contact the first molding layer ML1, and the plurality of upper first conductive posts CP1a_U may be portions of the plurality of first conductive posts CP1a that contact at least one of the third adhesive layer AL3 and the second molding layer ML2.

Each of the plurality of upper first conductive posts CP1a_U may be divided into a first portion CP1a_U1 and a second portion CP1a_U2. For example, the first portion CP1a_U1 of the upper first conductive post CP1a_U may be a portion of the upper first conductive post CP1a_U where sides of the upper first conductive post CP1a_U are in contact with the third adhesive layer AL3, and the second portion CP1a_U2 of the upper first conductive post CP1a_U may be a portion of the upper first conductive post CP1a_U where sides of the upper first conductive post CP1a_U come into contact with the second molding layer ML2.

In the first portion CP1a_U1 of each of the plurality of upper first conductive posts CP1a_U, a horizontal width of each of the plurality of upper first conductive posts CP1a_U may decrease downwards in the vertical direction (Z direction). In the second portion CP1a_U2 of each of the plurality of upper first conductive posts CP1a_U, a horizontal width of each of the plurality of upper first conductive posts CP1a_U may decrease downwards in the vertical direction (Z direction).

In some embodiments, a horizontal width of an upper surface of the first portion CP1a_U1 of each of the plurality of upper first conductive posts CP1a_U may be greater than the horizontal width of the lower surface of the second portion CP1a_U2 of each of the plurality of upper first conductive posts CP1a_U. For example, a portion of the upper surface of each of the first portions CP1a_U1 of the plurality of upper first conductive posts CP1a_U may be in contact with a lower surface of each of the second portions CP1a_U2 of the plurality of upper first conductive posts CP1a_U, and another portion of each of the first portions CP1a_U1 of the plurality of upper first conductive posts CP1a_U may be in contact with the second molding layer ML2.

The plurality of second conductive posts CP2a may extend in the vertical direction (Z direction) from the second semiconductor chip 200 to the redistribution structure RDL. For example, the plurality of second conductive posts CP2a may penetrate the first molding layer ML1, the third adhesive layer AL3, and the second molding layer ML2. For example, the plurality of second conductive posts CP2a may be in contact with the plurality of second input/output terminals 210 of the second semiconductor chip 200 and the redistribution pattern RP of the redistribution structure RDL. The plurality of second conductive posts CP2a may electrically connect the second semiconductor chip 200 to the redistribution structure RDL.

The plurality of second conductive posts CP2a may include a plurality of lower second conductive posts CP2a_L and a plurality of upper second conductive posts CP2a_U. The plurality of lower second conductive posts CP2a_L may be portions that contact the first molding layer ML1 among the plurality of second conductive posts CP2a, and the plurality of upper second conductive posts CP2a_U may be portions that contact at least one of the third adhesive layer AL3 and the second molding layer ML2 among the plurality of second conductive posts CP2a.

Each of the plurality of upper second conductive posts CP2a_U may be divided into a first portion CP2a_U1 and a second portion CP2a_U2. For example, the first portion CP2a_U1 of the upper second conductive post CP2a_U may be a portion where a side surface of the upper second conductive post CP2a_U among the upper second conductive posts CP2a_U is in contact with the third adhesive layer AL3, and the second portion CP2a_U2 of the upper second conductive post CP2a_U may be a portion where a side surface of the upper second conductive post CP2a_U among the upper second conductive posts CP2a_U is in contact with the second molding layer ML2.

In the first portion CP2a_U1 of each of the plurality of upper second conductive posts CP2a_U, a horizontal width of each of the plurality of upper second conductive posts CP2a_U may decrease downwards in the vertical direction (Z direction). In the second portion CP2a_U2 of each of the plurality of upper second conductive posts CP2a_U, a horizontal width of each of the plurality of upper second conductive posts CP2a_U may decrease downwards in the vertical direction (Z direction).

In some embodiments, a horizontal width of an upper surface of the first portion CP2a_U1 of each of the plurality of upper second conductive posts CP2a_U may be greater than a horizontal width of the lower surface of the second portion CP2a_U2 of each of the plurality of upper second conductive posts CP2a_U. For example, a portion of the upper surface of each of the first portions CP2a_U1 of the plurality of upper second conductive posts CP2a_U may be in contact with a lower surface of each of the second portions CP2a_U2 of the plurality of upper second conductive posts CP2a_U, and another portion of the first portions CP2a_U1 of each of the plurality of upper second conductive posts CP2a_U may be in contact with the second molding layer ML2.

Each of the plurality of first conductive posts CP1a and the plurality of second conductive posts CP2a of the semiconductor package 1000a of the disclosure may include portions having different horizontal widths. Accordingly, the durability of the plurality of first conductive posts CP1a and the plurality of second conductive posts CP2a may be improved.

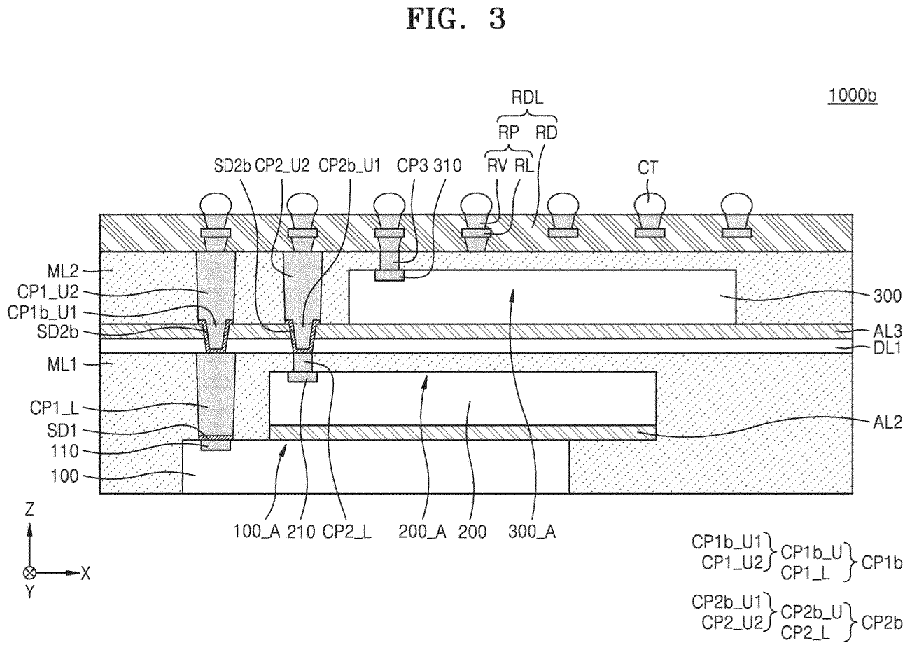

FIG. 3 is a schematic cross-sectional view showing a semiconductor package 1000b according to one or more embodiments.

Most of the components constituting the semiconductor package 1000b described below and the materials constituting the components are substantially the same as or similar to those described above with respect to FIG. 1. Therefore, for convenience of explanation, differences between the semiconductor package 1000b of FIG. 3 and the semiconductor package 1000 of FIG. 1 described above are mainly explained.

Referring to FIG. 3, the semiconductor package 1000b may include a first semiconductor chip 100, a plurality of first conductive posts CP1b, a first molding layer ML1, a second adhesive layer AL2, a second semiconductor chip 200, a plurality of second conductive posts CP2b, a second molding layer ML2, a third adhesive layer AL3, a third semiconductor chip 300, a plurality of third conductive posts CP3, and a redistribution structure RDL. The semiconductor package 1000b may further include a first insulating layer DL1. In some embodiments, the semiconductor package 1000b may further include a first adhesive layer AL1 (see FIG. 1).

The first insulating layer DL1 may be located between the first molding layer ML1 and the third adhesive layer AL3. The first insulating layer DL1 may be located on an upper surface of the first molding layer ML1, and the third adhesive layer AL3 may be located on an upper surface of the first insulating layer DL1. For example, a side surface of the first insulating layer DL1 may be coplanar with a side surface of the first molding layer ML1 and a side surface of the third adhesive layer AL3. In some embodiments, after the first insulating layer DL1 is formed on the upper surface of the first molding layer ML1, the third adhesive layer AL3 may be applied onto the first insulating layer DL1.

The plurality of first conductive posts CP1b may include a plurality of upper first conductive posts CP1b_U and a plurality of lower first conductive posts CP1_L. The plurality of upper first conductive posts CP1b_U may be located on the plurality of lower first conductive posts CP1_L and may penetrate the first insulating layer DL1, the third adhesive layer AL3, and the second molding layer ML2 to come into contact with the redistribution structure RDL. For example, the plurality of upper first conductive posts CP1b_U may extend from a lower surface of the first insulating layer DL1 to an upper surface of the second molding layer ML2.

The plurality of upper first conductive posts CP1b_U may be divided into a first portion CP1b_U1 and a second portion CP1_U2. For example, the first portion CP1b_U1 of the plurality of upper first conductive posts CP1b_U may be a portion where a side surface of the upper first conductive post CP1b_U among the upper first conductive posts CP1b_U is in contact with at least one of the first insulating layer DL1 and the third adhesive layer AL3, and the second portion CP1_U2 of the upper first conductive post CP1b_U may be a portion where a side surface of the upper first conductive post CP1b_U among the upper first conductive posts CP1b_U is in contact with the second molding layer ML2.

In some embodiments, among the first portion CP1b_U1 of the plurality of upper first conductive posts CP1b_U, at a vertical level in which the upper surface of the first insulating layer DL1 and a lower surface of the third adhesive layer AL3 contact each other, a horizontal width of each of the plurality of upper first conductive posts CP1b_U may be discretely different.

In some embodiments, a slope of a side surface of the plurality of upper first conductive posts CP1b_U at a portion among the first portion CP1b_U1 of the plurality of upper first conductive posts CP1b_U that contacts the first insulating layer DL1 and a slope of a side surface of the plurality of upper first conductive posts CP1b_U at a portion among the first portion CP1b_U1 of the plurality of upper first conductive posts CP1b_U that contacts the third adhesive layer AL3 may be different from each other.

The plurality of second conductive posts CP2b may include a plurality of upper second conductive posts CP2b_U and a plurality of lower second conductive posts CP2_L. The plurality of upper second conductive posts CP2b_U are located on the plurality of lower second conductive posts CP2_L and may penetrate the first insulating layer DL1, the third adhesive layer AL3, and the second molding layer ML2 to contact the redistribution structure RDL. For example, the plurality of upper second conductive posts CP2b_U may extend from a lower surface of the first insulating layer DL1 to the upper surface of the second molding layer ML2.

The plurality of upper second conductive posts CP2b_U may be divided into a first portion CP2b_U1 and a second portion CP2_U2. For example, the first portion CP2b_U1 of the plurality of upper second conductive posts CP2b_U may be a portion where a side surface of the upper second conductive post CP2b_U among the upper second conductive posts CP2b_U is in contact with at least one of the first insulating layer DL1 and the third adhesive layer AL3, and the second portion CP2_U2 of the upper second conductive post CP2b_U may be a portion where a side surface of the upper second conductive post CP2b_U among the upper second conductive posts CP2b_U is in contact with the second molding layer ML2.

In some embodiments, at a vertical level where the upper surface of the first insulating layer DL1 and the lower surface of the third adhesive layer AL3 are in contact with the first portion CP2b_U1 of the plurality of upper second conductive posts CP2b_U, a horizontal width of each of the plurality of upper second conductive posts CP2b_U may be discretely different.

A portion of an upper seed layer SD2b may be located on side and bottom surfaces of the first portion CP1b_U1 of the upper first conductive post CP1b_U. For example, a portion of the upper seed layer SD2b may be disposed between the upper first conductive post CP1b_U and the first insulating layer DL1, between the upper first conductive post CP1b_U and the third adhesive layer AL3, and between the upper first conductive post CP1b_U and the lower first conductive post CP1_L.

Another portion of the upper seed layer SD2b may be located on side and bottom surfaces of the first portion CP2b_U1 of the upper second conductive post CP2b_U. For example, another portion of the upper seed layer SD2b may be disposed between the upper second conductive post CP2b_U and the first insulating layer DL1, between the upper second conductive post CP2b_U and the third adhesive layer AL3, and between the upper second conductive post CP2b_U and the lower second conductive post CP2_L.

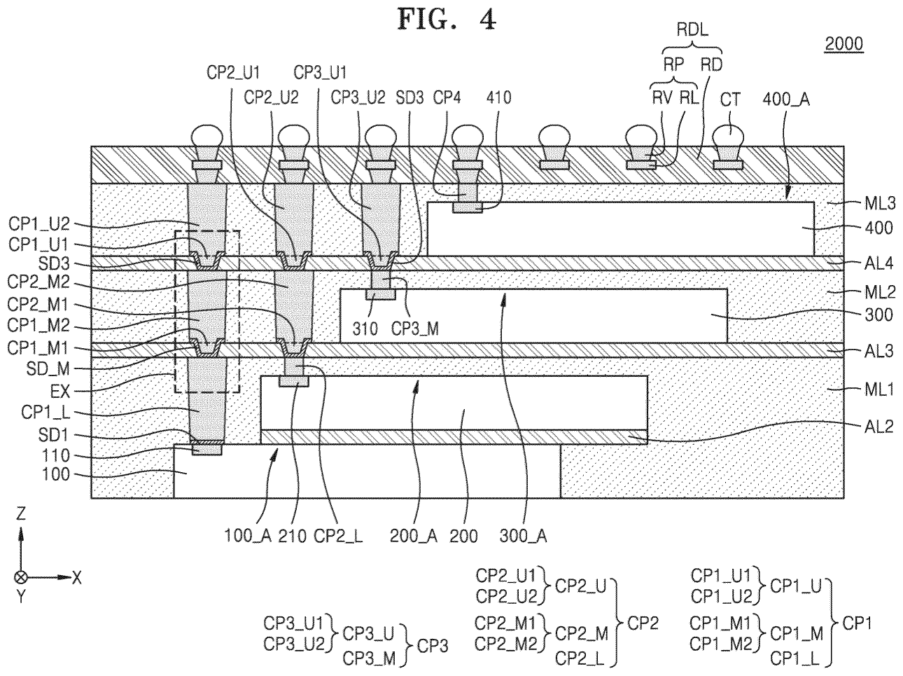

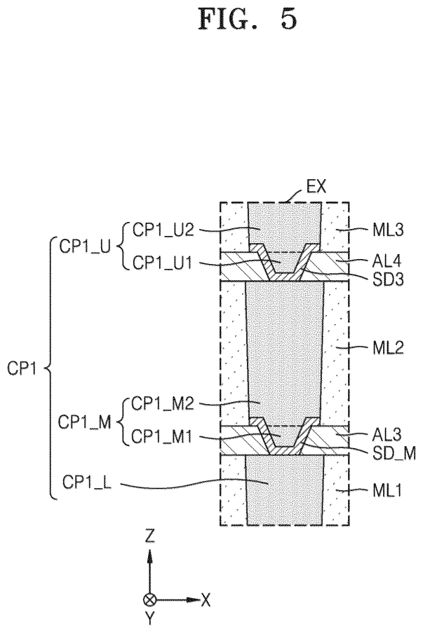

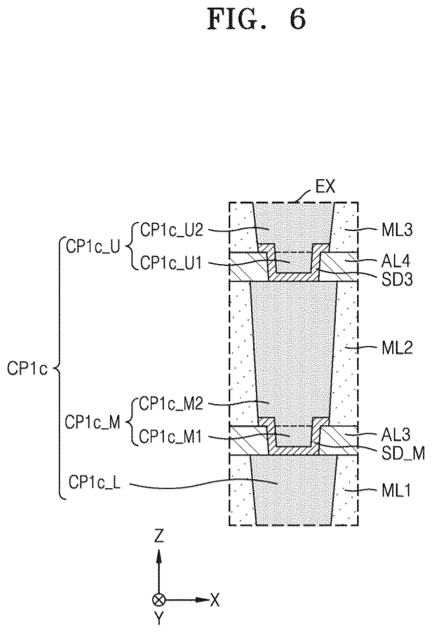

FIG. 4 is a schematic cross-sectional view showing a semiconductor package 2000 according to one or more embodiments. FIG. 5 is a schematic enlarged view showing a portion “EX” of the semiconductor package 2000 of FIG. 4. FIG. 6 is a schematic enlarged view showing a portion of the semiconductor package according to one or more embodiments.

Most of the components and materials forming the components of the semiconductor package 2000 described below are substantially the same as or similar to those described above in FIG. 1. Therefore, for convenience of explanation, differences between the semiconductor package 2000 of FIG. 4 and the semiconductor package 1000 of FIG. 1 are mainly explained.

Referring to FIG. 4, the semiconductor package 2000 may include a first semiconductor chip 100, a plurality of first conductive posts CP1, a first molding layer ML1, a second adhesive layer AL2, a second semiconductor chip 200, a plurality of second conductive posts CP2, a second molding layer ML2, a third adhesive layer AL3, a third semiconductor chip 300, a plurality of third conductive posts CP3, a fourth adhesive layer AL4, a fourth semiconductor chip 400, a plurality of fourth conductive posts CP4, a third molding layer ML3, and a redistribution structure RDL. In some embodiments, the semiconductor package 2000 may further include a first adhesive layer AL1 (see FIG. 1).

For example, the semiconductor package 2000 of FIG. 4 may be a package in which the fourth adhesive layer AL4 and the third molding layer ML3 are added to the semiconductor package 1000 of FIG. 1 in order to additionally stack the fourth semiconductor chip 400. In FIG. 4, the semiconductor package 2000 in which one semiconductor chip is added to the semiconductor package 1000 of FIG. 1 is illustrated, but the number of semiconductor chips added is not limited thereto.

The fourth adhesive layer AL4 may be located on the second molding layer ML2. For example, an area of an upper surface of the fourth adhesive layer AL4 may be greater than an area of a lower surface of the fourth semiconductor chip 400. In some embodiments, the fourth adhesive layer AL4 may be at least one of an NCF and a DAF.

The fourth semiconductor chip 400 may be located on the upper surface of the fourth adhesive layer AL4. The fourth semiconductor chip 400 may be offset from the first semiconductor chip 100, the second semiconductor chip 200, and the third semiconductor chip 300. In some embodiments, the fourth semiconductor chip 400 may be spaced apart from the plurality of first conductive posts CP1, the plurality of second conductive posts CP2, and the plurality of third conductive posts CP3. For example, the fourth semiconductor chip 400 may not overlap the plurality of first input/output terminals 110, the plurality of second input/output terminals 210, and the plurality of third input/output terminals 310 in the vertical direction (Z direction).

The fourth semiconductor chip 400 may include an active surface 400_A and an inactive surface opposite thereto. In some embodiments, the fourth semiconductor chip 400 may be located on the fourth adhesive layer AL4 so that the active surface 400_A of the fourth semiconductor chip 400 faces the redistribution structure RDL. For example, the fourth semiconductor chip 400 may be located on the fourth adhesive layer AL4 so that the active surface 400_A of the fourth semiconductor chip 400 faces upward in the vertical direction (Z direction).

In some embodiments, the fourth semiconductor chip 400 may further include a plurality of fourth input/output terminals 410. The plurality of fourth input/output terminals 410 may be located on the active surface 400_A of the fourth semiconductor chip 400.

In some embodiments, a plurality of individual devices of various types may be located on the active surface 400_A of the fourth semiconductor chip 400. Each of the plurality of individual devices of the fourth semiconductor chip 400 may be electrically connected to a wiring area of the fourth semiconductor chip 400.

For example, the plurality of individual devices of the fourth semiconductor chip 400 may include various micro electronic devices, for example, CMOS transistors, MOSFETs, a system LSI, an image sensor such as CISs, MEMSs, active elements, and passive elements.

The plurality of fourth conductive posts CP4 may be located on an upper surface of the fourth semiconductor chip 400 and may extend in the vertical direction (Z direction). For example, the plurality of fourth conductive posts CP4 may be located at the plurality of fourth input/output terminals 410 of the fourth semiconductor chip 400, respectively. For example, each of the plurality of fourth conductive posts CP4 may be referred to as a conductive pillar.

The plurality of first conductive posts CP1 may extend from the first semiconductor chip 100 to the redistribution structure RDL and may penetrate the first molding layer ML1, the third adhesive layer AL3, the second molding layer ML2, the fourth adhesive layer AL4, and the third molding layer ML3. The plurality of second conductive posts CP2 may extend from the second semiconductor chip 200 to the redistribution structure RDL and may penetrate the first molding layer ML1, the third adhesive layer AL3, the second molding layer ML2, the fourth adhesive layer AL4, and the third molding layer ML3. A plurality of third conductive posts CP3 may extend from the third semiconductor chip 300 to the redistribution structure RDL and may penetrate the second molding layer ML2, the fourth adhesive layer AL4, and the third molding layer ML3.

The plurality of first conductive posts CP1 may be spaced apart from the second semiconductor chip 200, the third semiconductor chip 300, and the fourth semiconductor chip 400. The plurality of second conductive posts CP2 may be spaced apart from the third semiconductor chip 300, and the fourth semiconductor chip 400. The plurality of third conductive posts CP3 may be spaced apart from the fourth semiconductor chip 400.

Each of the plurality of first conductive posts CP1 may include a lower first conductive post CP1_L, a middle first conductive post CP1_M, and an upper first conductive post CP1_U. For example, the lower first conductive post CP1_L may be a portion penetrating the first molding layer ML1, the middle first conductive post CP1_M may be a portion penetrating the third adhesive layer AL3 and the second molding layer ML2, and the upper first conductive post CP1_U may be a portion penetrating the fourth adhesive layer AL4 and the third molding layer ML3.

In some embodiments, the plurality of first conductive posts CP1 may penetrate a plurality of molding layers and adhesive layers to electrically connect the first semiconductor chip 100 to the redistribution structure RDL. For example, the lower first conductive post CP1_L may be a portion penetrating a molding layer that contacts the first semiconductor chip 100, the upper first conductive post CP1_U may be a portion penetrating a molding layer that contacts the redistribution structure RDL, and the middle first conductive post CP1_M may be a portion penetrating a molding layer located between the lower first conductive post CP1_L and the upper first conductive post CP1_U.

The middle first conductive post CP1_M of each of the plurality of first conductive posts CP1 may be divided into a first portion CP1_M1 and a second portion CP1_M2. For example, the first portion CP1_M1 of the middle first conductive post CP1_M may be a portion where a side of the middle first conductive post CP1_M among the middle first conductive posts CP1_M is in contact with the third adhesive layer AL3, and the second portion CP1_M2 of the middle first conductive post CP1_M may be a portion where a side of the middle first conductive post CP1_M among the middle first conductive posts CP1_M is in contact with the second molding layer ML2.

The upper first conductive post CP1_U of each of the plurality of first conductive posts CP1 may be divided into a first portion CP1_U1 and a second portion CP1_U2. For example, the first portion CP1_U1 of the upper first conductive post CP1_U may be a portion where a side surface of the upper first conductive post CP1_U among the upper first conductive posts CP1_U is in contact with the fourth adhesive layer AL4, and the second portion CP1_U2 of the upper first conductive post CP1_U may be a portion where a side surface of the upper first conductive post CP1_U among the upper first conductive posts CP1_U is in contact with the third molding layer ML3.

Each of the plurality of second conductive posts CP2 may include a lower second conductive post CP2_L, a middle second conductive post CP2_M, and an upper second conductive post CP2_U. For example, the lower second conductive post CP2_L may be a portion penetrating a portion of the first molding layer ML1, the middle second conductive post CP2_M may be a portion penetrating the third adhesive layer AL3 and the second molding layer ML2, and the upper second conductive post CP2_U may be a portion penetrating the fourth adhesive layer AL4 and the third molding layer ML3.

The middle second conductive post CP2_M of each of the plurality of second conductive posts CP2 may be divided into a first portion CP2_M1 and a second portion CP2_M2. For example, the first portion CP2_M1 of the middle second conductive post CP2_M may be a portion where a side surface of the middle second conductive post CP2_M among the middle second conductive posts CP2_M is in contact with the third adhesive layer AL3, and the second portion CP2_M2 of the middle second conductive post CP2_M may be a portion where a side surface of the middle second conductive post CP2_M among the middle second conductive posts CP2_M is in contact with the second molding layer ML2.

The upper second conductive post CP2_U of each of the plurality of second conductive posts CP2 may be divided into a first portion CP2_U1 and a second portion CP2_U2. For example, the first portion CP2_U1 of the upper second conductive post CP2_U may be a portion where a side surface of the upper second conductive post CP2_U among the upper second conductive posts CP2_U is in contact with the fourth adhesive layer AL4, and the second portion CP2_U2 of the upper second conductive post CP2_U may be a portion where a side surface of the upper second conductive post CP2_U among the upper second conductive posts CP2_U is in contact with the third molding layer ML3.

Each of the plurality of third conductive posts CP3 may be divided into a middle third conductive post CP3_M and an upper third conductive post CP3_U. For example, the middle third conductive post CP3_M may be a portion penetrating a portion of the second molding layer ML2, and the upper third conductive post CP3_U may be a portion penetrating the fourth adhesive layer AL4 and the third molding layer ML3.

The middle third conductive post CP3_M of each of the plurality of third conductive posts CP3 may be referred to as a lower third conductive post. For example, the middle third conductive post CP3_M may be referred to as a conductive pillar.

The upper third conductive post CP3_U of each of the plurality of third conductive posts CP3 may be divided into a first portion CP3_U1 and a second portion CP3_U2. For example, the first portion CP3_U1 of the upper third conductive post CP3_U may be a portion where a side surface of the upper third conductive post CP3_U among the upper third conductive posts CP3_U is in contact with the fourth adhesive layer AL4, and the second portion CP3_U2 of the upper third conductive post CP3_U may be a portion where a side surface of the upper third conductive post CP3_U among the upper third conductive posts CP3_U is in contact with the third molding layer ML3.

Referring to FIGS. 5 and 6, a horizontal width of the middle first conductive post CP1_M on an upper surface of the first portion CP1_M1 of the middle first conductive post CP1_M of each of the plurality of first conductive posts CP1 and a horizontal width of the middle first conductive post CP1_M on a lower surface of the second portion CP1_M2 of the middle first conductive post CP1_M may be different. For example, a portion of the lower surface of the second portion CP1_M2 of the middle first conductive post CP1_M may be in contact with the first portion CP1_M1 of the middle first conductive post CP1_M, and another portion of the lower surface of the second portion CP1_M2 may protrude outside the first portion CP1_M1 of the middle first conductive post CP1_M.

A horizontal width of the upper first conductive post CP1_U on an upper surface of the first portion CP1_U1 of the upper first conductive post CP1_U of each of the plurality of first conductive posts CP1 and a horizontal width of the upper first conductive post CP1_U on a lower surface of the second portion CP1_U2 of the upper first conductive post CP1_U may be different. For example, a portion of a lower surface of the second portion CP1_U2 of the upper first conductive post CP1_U may be in contact with the first portion CP1_U1 of the upper first conductive post CP1_U, and another portion may protrude outside the first portion CP1_U1 of the upper first conductive post CP1_U.

In some embodiments, the lower first conductive post CP1_L of each of the plurality of first conductive posts CP1 may have a narrower horizontal width towards the first semiconductor chip 100. For example, the lower first conductive post CP1_L may have a horizontal width that narrows downwards in the vertical direction (Z direction).

Each of the first portion CP1_M1 and the second portion CP1_M2 of the middle first conductive post CP1_M of each of the plurality of first conductive posts CP1 may have a horizontal width that narrows towards the first semiconductor chip 100. For example, each of the first portion CP1_M1 and the second portion CP1_M2 of the middle first conductive post CP1_M may have a horizontal width that narrows downwards in the vertical direction (Z direction).

Each of the first portion CP1_U1 and the second portion CP1_U2 of the upper first conductive post CP1_U of each of the plurality of first conductive posts CP1 may have a horizontal width that narrows towards the first semiconductor chip 100. For example, the first portion CP1_U1 and the second portion CP1_U2 of the upper first conductive post CP1_U may each have the horizontal width that becomes narrower downwards in the vertical direction (Z direction).

In some embodiments, an inclination of a side surface of the middle first conductive post CP1_M in the first portion CP1_M1 of the middle first conductive post CP1_M of each of the plurality of first challenge posts CP1 and an inclination of a side surface of the middle first challenge post CP1_M in the second portion CP1_M2 of the middle first conductive post CP1_M of each of the plurality of first challenge posts CP1 may be different.

An inclination of a side surface of the upper first conductive post CP1_U in the first portion CP1_U1 of the upper first conductive post CP1_U of each of the plurality of first conductive posts CP1 and an inclination of a side surface of the upper first conductive post CP1_U in the second portion CP1_U2 of the upper first conductive post CP1_U of each of the plurality of first conductive posts CP1 may be different.

In some embodiments, as illustrated in FIG. 5, the inclination of the side surface of the middle first conductive post CP1_M in the first portion CP1_M1 of the middle first conductive post CP1_M of each of the plurality of first conductive posts CP1 may be less than the inclination of the side surface of the middle first conductive post CP1_M in the second portion CP1_M2 of the middle first conductive post CP1_M of each of the plurality of first conductive posts CP1.

The inclination of the side surface of the upper first conductive post CP1_U in the first portion CP1_U1 of the upper first conductive post CP1_U of each of the plurality of first conductive posts CP1 may be less than the inclination of the side surface of the middle first conductive post CP1_M in the second portion CP1_U2 of the upper first conductive post CP1_U of each of the plurality of first conductive posts CP1.

In some embodiments, as illustrated in FIG. 6, an inclination of a side surface of a middle first conductive post CP1c_M in a first portion CP1_M1 of the middle first conductive post CP1c_M of each of the plurality of first conductive posts CP1c may be greater than an inclination of a side surface of the middle first conductive post CP1c_M in a second portion CP1c_M2 of the middle first conductive post CP1c_M of each of the plurality of first conductive posts CP1c.

An inclination of a side surface of an upper first conductive post CP1c_U at a first portion CP1c_U1 of the upper first conductive post CP1c_U of each of the plurality of first conductive posts CP1c may be greater than an inclination of the side surface of the middle first conductive post CP1c_M at the second portion CP1c_U2 of the upper first conductive post CP1c_U of each of the plurality of first conductive posts CP1c.

For example, the middle second conductive post CP2_M of each of the plurality of second conductive posts CP2 may be substantially equal to the middle second conductive post CP2_M of each of the plurality of first conductive posts CP1. The upper second conductive post CP2_U of each of the plurality of second conductive posts CP2 and the upper third conductive post CP3_U of each of the plurality of third conductive posts CP3 may be substantially equal to the upper first conductive post CP1_U of each of the plurality of first conductive posts CP1.

Referring again to FIG. 4, the semiconductor package 2000 may further include a lower seed layer SD1, a middle seed layer SD_M, and an upper seed layer SD3.

The lower seed layer SD1 may be located between the lower first conductive post CP1_L of each of the plurality of first conductive posts CP1 and the first semiconductor chip 100.

A portion of the middle seed layer SD_M may be located between the middle first conductive post CP1_M of each of the plurality of first conductive posts CP1 and the third adhesive layer AL3, and between the middle first conductive post CP1_M and the lower first conductive post CP1_L. Another portion of the middle seed layer SD_M may be located between the middle second conductive post CP2_M of each of the plurality of second conductive posts CP2 and the third adhesive layer AL3 and between the middle second conductive post CP2_M and the lower second conductive post CP2_L.

A portion of the upper seed layer SD3 may be located between the upper first conductive post CP1_U of each of the plurality of first conductive posts CP1 and the fourth adhesive layer AL4 and between the upper first conductive post CP1_U and the middle first conductive post CP1_M. Another portion of the upper seed layer SD3 may be located between each of the upper second conductive posts CP2_U of the plurality of second conductive posts CP2 and the fourth adhesive layer AL4 and between the upper second conductive post CP2_U and the middle second conductive post CP2_M.

The third molding layer ML3 may be located on the fourth adhesive layer AL4. The third molding layer ML3 may surround the plurality of upper first conductive posts CP1_U, the plurality of upper second conductive posts CP2_U, the plurality of upper third conductive posts CP3_U, the fourth semiconductor chip 400, and the plurality of fourth conductive posts CP4.

In some embodiments, a side surface of the third molding layer ML3, a side surface of the fourth adhesive layer AL4, a side surface of the second molding layer ML2, a side surface of the third adhesive layer AL3, and a side surface of the first molding layer ML1 may be coplanar. In some embodiments, an upper surface of the third molding layer ML3, upper surfaces of the plurality of upper first conductive posts CP1_U, upper surfaces of the plurality of upper second conductive posts CP2_U, upper surfaces of the plurality of upper third conductive posts CP3_U, and upper surfaces of the plurality of fourth conductive posts CP4 may be coplanar.

In some embodiments, the third molding layer ML3 may include an epoxy resin or a polyimide resin, and the like. The third molding layer ML3 may be located on the fourth adhesive layer AL4. The third molding layer ML3 may include, for example, an EMC.

A redistribution structure RDL may be located on the third molding layer ML3. The redistribution structure RDL may be in contact with the plurality of first conductive posts CP1, the plurality of second conductive posts CP2, the plurality of third conductive posts CP3, and the plurality of fourth conductive posts CP4.

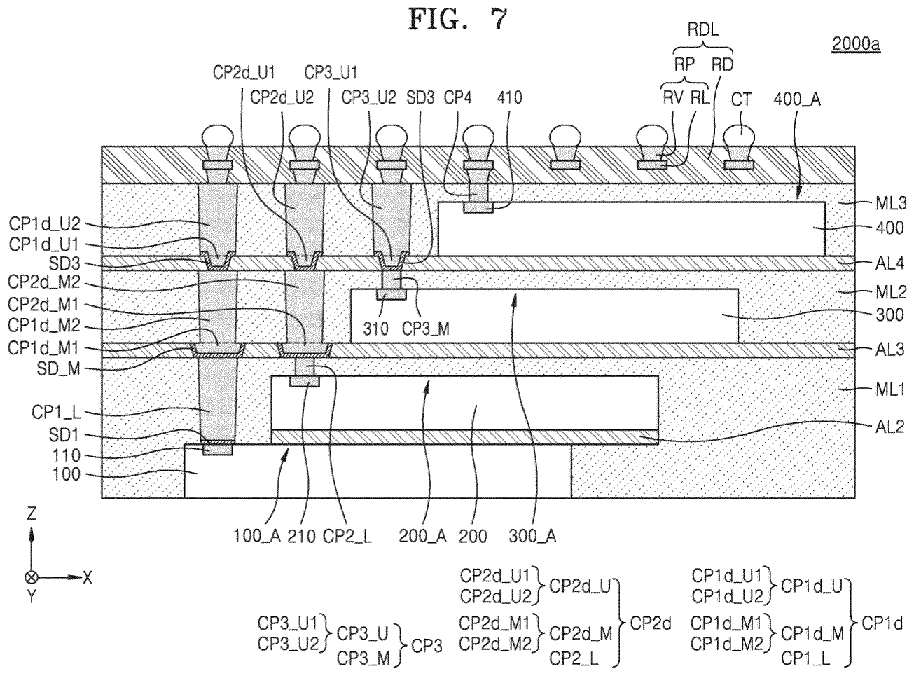

FIG. 7 is a schematic cross-sectional view showing a semiconductor package 2000a according to one or more embodiments.

Most of the components constituting the semiconductor package 2000a described below and the materials constituting the components are substantially the same as or similar to those described above with reference to FIG. 4. Therefore, for convenience of explanation, differences between the semiconductor package 2000a of FIG. 7 and the semiconductor package 2000 of FIG. 4 described above are mainly explained.

Referring to FIG. 7, the semiconductor package 2000a may include a first semiconductor chip 100, a plurality of first conductive posts CP1d, a first molding layer ML1, a second adhesive layer AL2, a second semiconductor chip 200, a plurality of second conductive posts CP2d, a second molding layer ML2, a third adhesive layer AL3, a third semiconductor chip 300, a plurality of third conductive posts CP3, a fourth adhesive layer AL4, a fourth semiconductor chip 400, a plurality of fourth conductive posts CP4, a third molding layer ML3, and a redistribution structure RDL. In some embodiments, the semiconductor package 2000a may further include a first adhesive layer AL1 (see FIG. 1).

Each of the plurality of first conductive posts CP1d may extend from the first semiconductor chip 100 to the redistribution structure RDL. The plurality of first conductive posts CP1d may penetrate the third molding layer ML3, the fourth adhesive layer AL4, the second molding layer ML2, the third adhesive layer AL3, and the first molding layer ML1.

Each of the plurality of first conductive posts CP1d may include a lower first conductive post CP1_L, a middle first conductive post CP1d_M, and an upper first conductive post CP1d_U. The lower first conductive post CP1_L may be a portion that contacts the first molding layer ML1 of the first conductive post CP1d, the middle first conductive post CP1d_M may be a portion of the first conductive post CP1d that contacts at least one of the third adhesive layer AL3 and the second molding layer ML2, and the upper first conductive post CP1d_U may be a portion of the first conductive post CP1d that contacts at least one of the fourth adhesive layer AL4 and the third molding layer ML3.

The middle first conductive post CP1d_M of each of the plurality of first conductive posts CP1d may include a first portion CP1d_M1 and a second portion CP1d_M2. The first portion CP1d_M1 of the middle first conductive post CP1d_M may be a portion of the middle first conductive post CP1d_M in which a side surface of the middle first conductive post CP1d_M is in contact with the third adhesive layer AL3. The second portion CP1d_M2 of the middle first conductive post CP1d_M may be a portion of the middle first conductive post CP1d_M in which a side of the middle first conductive post CP1d_M is in contact with the second molding layer ML2.

The upper first conductive post CP1d_U of each of the plurality of first conductive posts CP1d may include a first portion CP1d_U1 and a second portion CP1d_U2. The first portion CP1d_U1 of the upper first conductive post CP1d_U may be a portion where a side surface of the upper first conductive post CP1d_U among the upper first conductive posts CP1d_U is in contact with the fourth adhesive layer AL4. The second portion CP1d_U2 of the upper first conductive post CP1d_U may be a portion where a side surface of the upper first conductive post CP1d_U among the upper first conductive posts CP1d_U is in contact with the third molding layer ML3.

In some embodiments, each of the plurality of first conductive posts CP1d may include portions where a horizontal width is discretely different. For example, at a boundary between an adhesive layer and a molding layer, the horizontal widths of the plurality of first conductive posts CP1d may be discretely different.

A size relationship between the horizontal width of the first portion CP1d_M1 of the middle first conductive post CP1d_M and the horizontal width of the second portion CP1d_M2 of the middle first conductive post CP1d_M may be independent from a size relationship between the horizontal width of the first portion CP1d_U1 of the upper first conductive post CP1d_U and the horizontal width of the second portion CP1d_U2 of the upper first conductive post CP1d_U.

For example, the horizontal width of the middle first conductive post CP1d_M in the first portion CP1d_M1 of the middle first conductive post CP1d_M may be greater than the horizontal width of the middle first conductive post CP1d_M in the second portion CP1d_M2 of the middle first conductive post CP1d_M. The horizontal width of the upper first conductive post CP1d_U in the first portion CP1d_U1 of the upper first conductive post CP1d_U may be less than the horizontal width of the upper first conductive post CP1d_U in the second portion CP1d_U2 of the upper first conductive post CP1d_U.

The plurality of second conductive posts CP2d may also be substantially equal to the plurality of first conductive posts CP1d. The plurality of second conductive posts CP2d may include a lower second conductive post CP2_L, a middle second conductive post CP2d_M, and an upper second conductive post CP2d_U. Each of the plurality of second conductive posts CP2d may include portions having discretely different horizontal widths. For example, at a boundary between an adhesive layer and a molding layer, the horizontal width of each of the plurality of second conductive posts CP2d may discretely vary.

A size relationship between a horizontal width of the first portion CP2d_M1 of a middle second conductive post CP2d_M and a horizontal width of a second portion CP2d_M2 of the middle second conductive post CP2d_M may be independent from a size relationship between a horizontal width of a first portion CP2d_U1 of the upper second conductive post CP2d_U and a horizontal width of a second portion CP2d_U2 of the upper second conductive post CP2d_U.

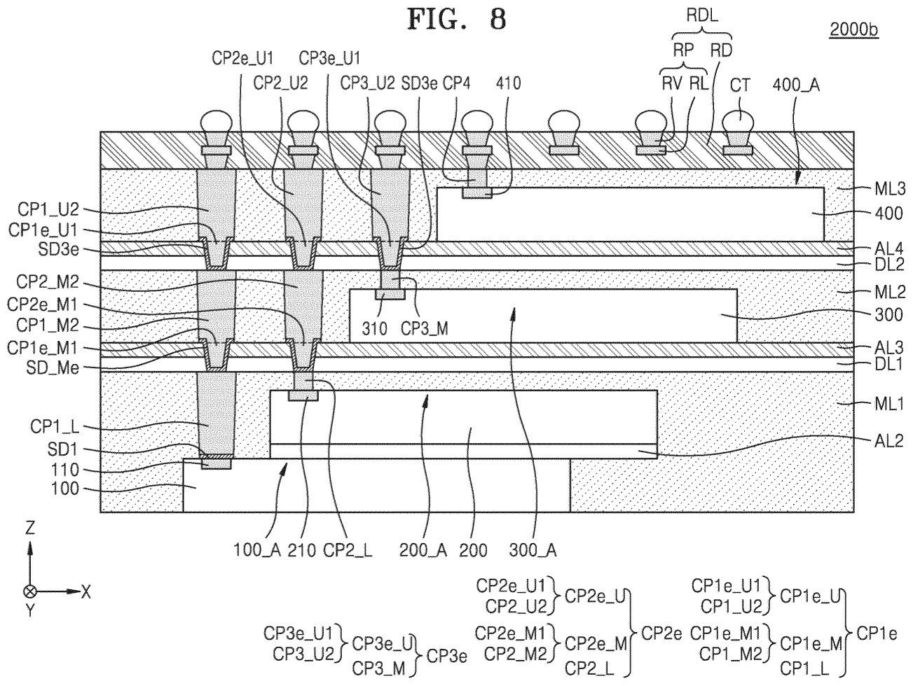

FIG. 8 is a schematic cross-sectional view showing a semiconductor package 2000b according to one or more embodiments.

Most of the components constituting the semiconductor package 2000b described below and the materials constituting the components are substantially the same as or similar to those described above with reference to FIG. 4. Therefore, for convenience of explanation, differences between the semiconductor package 2000b of FIG. 8 and the semiconductor package 2000 of FIG. 4 described above are mainly described.

Referring to FIG. 8, the semiconductor package 2000b may include a first semiconductor chip 100, a plurality of first conductive posts CP1e, a first molding layer ML1, a second adhesive layer AL2, a second semiconductor chip 200, a plurality of second conductive posts CP2e, a second molding layer ML2, a third adhesive layer AL3, a third semiconductor chip 300, a plurality of third conductive posts CP3e, a fourth adhesive layer AL4, a fourth semiconductor chip 400, a plurality of fourth conductive posts CP4, a third molding layer ML3, and a redistribution structure RDL. The semiconductor package 2000b may further include a first insulating layer DL1 and a second insulating layer DL2. In some embodiments, the semiconductor package 2000b may further include a first adhesive layer AL1 (see FIG. 1).

The first insulating layer DL1 may be located on an upper surface of the first molding layer ML1 and may be located between the first molding layer ML1 and the third adhesive layer AL3. For example, the third adhesive layer AL3 may be located on the first insulating layer DL1. In some embodiments, after the first insulating layer DL1 is formed on the upper surface of the first molding layer ML1, the third adhesive layer AL3 may be applied onto the first insulating layer DL1. In some embodiments, a side surface of the first insulating layer DL1 may be coplanar with a side surface of the first molding layer ML1 and a side surface of the third adhesive layer AL3.

The second insulating layer DL2 may be located on an upper surface of the second molding layer ML2 and may be located between the second molding layer ML2 and the fourth adhesive layer AL4. For example, the fourth adhesive layer AL4 may be located on the second insulating layer DL2. In some embodiments, after forming the second insulating layer DL2 on the upper surface of the second molding layer ML2, the fourth adhesive layer AL4 may be applied onto the second insulating layer DL2. In some embodiments, a side surface of the second insulating layer DL2 may be coplanar with a side surface of the second molding layer ML2 and a side surface of the fourth adhesive layer AL4.

Each of the plurality of first conductive posts CP1e may include a lower first conductive post CP1_L, a middle first conductive post CP1e_M, and an upper first conductive post CP1e_U. The lower first conductive post CP1_L may be a portion where a side surface of the first conductive post CP1e among the first conductive posts CP1e contacts the first molding layer ML1. The middle first conductive post CP1e_M may be a portion where the side surface of the first conductive post CP1e among the first conductive posts CP1e is in contact with at least one of the first insulating layer DL1, the third adhesive layer AL3, and the second molding layer ML2. The upper first conductive post CP1e_U may be a portion where the side surface of the first conductive post CP1e among the first conductive posts CP1e is in contact with at least one of the second insulating layer DL2, the fourth adhesive layer AL4, and the third molding layer ML3.

The middle first conductive post CP1e_M of each of the plurality of first conductive posts CP1e may be divided into a first portion CP1e_M1 and a second portion CP1_M2. For example, the first portion CP1e_M1 of the middle first conductive post CP1e_M may be a portion where a side surface of the middle first conductive post CP1e_M among the middle first conductive posts CP1e_M is in contact with at least one of the first insulating layer DL1 and the third adhesive layer AL3, and the second portion CP1_M2 of the middle first conductive post CP1e_M may be a portion where the side surface of the middle first conductive post CP1e_M among the middle first conductive posts CP1e_M is in contact with the second molding layer ML2.

In some embodiments, a horizontal width of the middle first conductive post CP1e_M may be discretely varied at a vertical level where an upper surface of the first insulating layer DL1 and a lower surface of the third adhesive layer AL3 are in contact with the first portion CP1e_M1 of the middle first conductive post CP1e_M.

In some embodiments, an inclination of the side surface of the middle first conductive post CP1e_M at a portion of the first portion CP1e_M1 of the middle first conductive post CP1e_M that is in contact with the first insulating layer DL1 and an inclination of the side surface of the middle first conductive post CP1e_M at a portion of the first portion CP1e_M1 of the middle first conductive post CP1e_M that is in contact with the third adhesive layer AL3 among the first portion CP1e_M1 of the middle first conductive post CP1e_M may be different from each other.

Each of the plurality of first conductive posts CP1e may be divided into a first portion CP1e_U1 and a second portion CP1_U2. For example, the first portion CP1e_U1 of the upper first conductive post CP1e_U may be a portion where a side surface of the upper first conductive post CP1e_U among the upper first conductive posts CP1e_U is in contact with at least one of the second insulating layer DL2 and the fourth adhesive layer AL4, and the second portion CP1_U2 of the upper first conductive post CP1e_U may be a portion where the side surface of the upper first conductive post CP1e_U among the upper first conductive posts CP1e_U is in contact with the third molding layer ML3.

In some embodiments, a horizontal width of the upper first conductive post CP1e_U may be discretely varied at a vertical level where an upper surface of the second insulating layer DL2 and a lower surface of the fourth adhesive layer AL4 are in contact with the first portion CP1e_U1 of the upper first conductive post CP1e_U.

In some embodiments, an inclination of the side surface of the upper first conductive post CP1e_U at a portion of the first portion CP1e_U1 of the upper first conductive post CP1e_U that is in contact with the second insulating layer DL2 and an inclination of side surfaces of the plurality of upper first conductive posts CP1b_U at the portion of the first portion CP1e_U1 of the upper first conductive post CP1e_U that is in contact with the fourth adhesive layer AL4 may be different from each other.

Each of the plurality of second conductive posts CP2e may include a lower second conductive post CP2_L, a middle second conductive post CP2e_M, and an upper second conductive post CP2e_U. The lower second conductive post CP2_L may be a portion of the second conductive post CP2e among the second conductive posts CP2e where a side surface of the second conductive post CP2e is in contact with the first molding layer ML1. The middle second conductive post CP2e_M may be a portion of the second conductive post CP2e among the second conductive posts CP2e where the side surface of the second conductive post CP2e is in contact with at least one of the first insulating layer DL1, the third adhesive layer AL3, and the second molding layer ML2. The upper second conductive post CP2e_U may be a portion of the second conductive post CP2e among the second conductive posts CP2e where the side surface of the second conductive post CP2e is in contact with at least one of the second insulating layer DL2, the fourth adhesive layer AL4, and the third molding layer ML3.

Each of the plurality of middle second conductive posts CP2e may be divided into a first portion CP2e_M1 and a second portion CP2_M2. For example, the first portion CP2e_M1 of the middle second conductive post CP2e_M may be a portion where a side surface of the middle second conductive post CP2e_M is in contact with at least one of the first insulating layer DL1 and the third adhesive layer AL3, and the second portion CP2_M2 of the middle second conductive post CP2e_M may be a portion where the side surface of the middle first conductive post CP1e_M of the second conductive post CP2e_M is in contact with the second molding layer ML2.

In some embodiments, a horizontal width of the middle second conductive post CP2e_M may be discretely changed at a vertical level where the upper surface of the second insulating layer DL2 and a lower surface of the fourth adhesive layer AL4 are in contact with the first portion CP2e_M1 of the middle second conductive post CP2e_M.

In some embodiments, an inclination of the side surface of the middle second conductive post CP2e_M at a portion of the first portion CP2e_M1 of the middle second conductive post CP2e_M in contact with the first insulating layer DL1 and an inclination of a side surface of the upper first conductive post CP1e_U at a portion of the middle second conductive post CP2e_M in contact with the third adhesive layer AL3 of the first portion CP2e_M1 may be different from each other.

The upper second conductive post CP2e_U of each of the plurality of second conductive posts CP2e may be divided into a first portion CP2e_U1 and a second portion CP2e_U2. For example, the first portion CP2e_U1 of the upper second conductive post CP2e_U may be a portion where a side surface of the upper second conductive post CP2e_U among the upper second conductive posts CP2e_U is in contact with at least one of the second insulating layer DL2 and the fourth adhesive layer AL4, and the second portion CP2_U2 of the upper second conductive post CP2e_U may be a portion where the side surface of the upper second conductive post CP2e_U among the upper second conductive posts CP2e_U is in contact with the third molding layer ML3.

In some embodiments, a horizontal width of the upper second conductive post CP2e_U may be discretely varied at a vertical level where the upper surface of the second insulating layer DL2 and the lower surface of the fourth adhesive layer AL4 are in contact with the first portion CP2e_U1 of the upper second conductive post CP2e_U.

In some embodiments, an inclination of the side surface of the upper second conductive post CP2e_U at a portion of the first portion CP2e_U1 of the upper second conductive post CP2e_U that is in contact with the second insulating layer DL2 and an inclination of the side surface of the plurality of upper second conductive posts CP2e_U at the portion of the first portion CP2e_U1 of the upper second conductive post CP2e_U that is in contact with the fourth adhesive layer AL4 may be different from each other.

The upper third conductive post CP3e_U of each of the plurality of third conductive posts CP3e may be divided into a first portion CP3e_U1 and a second portion CP3_U2. For example, the first portion CP3e_U1 of the upper third conductive post CP3e_U may be a portion where a side surface of the upper third conductive post CP3e_U among the upper third conductive posts CP3e_U is in contact with at least one of the second insulating layer DL2 and the fourth adhesive layer AL4, and the second portion CP3_U2 of the upper third conductive post CP3e_U may be a portion where a side surface of the upper second conductive post CP2e_U among the upper second conductive posts CP2e_U is in contact with the third molding layer ML3.

In some embodiments, a horizontal width of the upper third conductive post CP3e_U may be discretely varied at a vertical level where the upper surface of the second insulating layer DL2 and the lower surface of the fourth adhesive layer AL4 are in contact with the first portion CP3e_U1 of the upper third conductive post CP3e_U.

In some embodiments, an inclination of the side surface of the upper third conductive post CP3e_U at the portion of the first portion CP3e_U1 of the upper third conductive post CP3e_U that is in contact with the second insulating layer DL2 and an inclination of the side surface of the plurality of upper third conductive posts CP3e_U at the portion of the first portion CP3e_U1 of the upper third conductive post CP3e_U that is in contact with the fourth adhesive layer AL4 may be different from each other.

A portion of the middle seed layer SD_Me may be located on side and bottom surfaces of the first portion CP1e_M1 of the middle first conductive post CP1e_M. For example, a portion of the middle seed layer SD_Me may be disposed between the middle first conductive post CP1e_M and the first insulating layer DL1, between the middle first conductive post CP1e_M and the third adhesive layer AL3, and between the middle first conductive post CP1e_M and a lower first conductive post CP1_L.

Another portion of the middle seed layer SD_Me may be located on side and bottom surfaces of the first portion CP2e_M1 of the middle second conductive post CP2e_M. For example, another portion of the middle seed layer SD_Me may be disposed between the middle second conductive post CP2e_M and the first insulating layer DL1, between the middle second conductive post CP2e_M and the third adhesive layer AL3, and between the middle second conductive post CP2e_M and the lower second conductive post CP2_L.

A portion of the upper seed layer SD3e may be located on side and lower surfaces of the first portion CP1e_U1 of the upper first conductive post CP1e_U. For example, a portion of the upper seed layer SD3e may be disposed between the upper first conductive post CP1e_U and the second insulating layer DL2, between the upper first conductive post CP1e_U and the fourth adhesive layer AL4, and between the upper first conductive post CP1e_U and the middle first conductive post CP1e_M.

Another portion of the upper seed layer SD3e may be located on side and bottom surfaces of the first portion CP2e_U1 of the upper second conductive post CP2e_U. For example, another portion of the upper seed layer SD3e may be disposed between the upper second conductive post CP2e_U and the second insulating layer DL2, between the upper second conductive post CP2e_U and the fourth adhesive layer AL4, and between the upper second conductive post CP2e_U and the middle second conductive post CP2e_M.

FIGS. 9A to 9T are diagrams showing a method of manufacturing a semiconductor package according to one or more embodiments according to a process sequence.

FIGS. 9A to 9T are schematic diagrams showing a process of manufacturing the semiconductor package 2000 (see FIG. 4) of FIG. 4. The semiconductor package 1000 (see FIG. 1) of FIG. 1 in which three semiconductor chips are stacked or a semiconductor package in which four or more semiconductor chips are stacked may be manufactured using a method similar to the semiconductor package manufacturing method illustrated in FIGS. 9A to 9T. Through the method of manufacturing a semiconductor package according to the disclosure, in a process of stacking semiconductor chips, the phenomenon of fillet generation between the semiconductor chip and the adhesive layer may be suppressed.

The method of manufacturing a semiconductor package may include: applying a first adhesive layer AL1 to a carrier substrate CR, and then stacking a first semiconductor chip 100 on the first adhesive layer AL1; forming a plurality of lower first conductive posts CP1_L on the first semiconductor chip 100; offset-stacking a second semiconductor chip 200 on the first semiconductor chip 100 so that the second semiconductor chip 200 and the plurality of lower first conductive posts CP1_L are spaced apart from each other; forming a first molding layer ML1 located on a first adhesive layer AL1 and surrounding the plurality of lower first conductive posts CP1_L, a plurality of lower second conductive posts CP2_L, and the second semiconductor chip 200; applying a third adhesive layer AL3 on the first molding layer ML1, and then, arranging a third semiconductor chip 300 on the third adhesive layer AL3; forming a plurality of middle first conductive posts CP1_M and a plurality of middle second conductive posts CP2_M; forming a second molding layer ML2 located on the third adhesive layer AL3 and surrounding the plurality of middle first conductive posts CP1_M, the plurality of middle second conductive posts CP2_M, a plurality of middle third conductive posts CP3_M, and the third semiconductor chip 300; applying a fourth adhesive layer AL4 on a second molding layer ML2, and then disposing a fourth semiconductor chip 400 on the fourth adhesive layer AL4; forming a plurality of upper first conductive posts CP1_U, a plurality of upper second conductive posts CP2_U, and a plurality of upper third conductive posts CP3_U; forming a third molding layer ML3 located on the third adhesive layer AL3 and surrounding the plurality of upper first conductive posts CP1_U, the plurality of upper second conductive posts CP2_U, the plurality of upper third conductive posts CP3_U, and the plurality of fourth conductive posts CP4; and forming a redistribution structure RDL on the third molding layer ML3.

Referring to FIG. 9A, a first adhesive layer AL1 may be applied on a carrier substrate CR. For example, the first adhesive layer AL1 may be applied to cover an entire upper surface of the carrier substrate CR. For example, an area of a lower surface of the first adhesive layer AL1 may be equal to an area of an upper surface of the carrier substrate CR.

Referring to FIG. 9B, a first semiconductor chip 100 may be placed on the first adhesive layer AL1. For example, an area of a lower surface of the first semiconductor chip 100 may be less than an area of an upper surface of the first adhesive layer AL1. For example, the first semiconductor chip 100 may be attached on the first adhesive layer AL1 so that an active surface 100_A of the first semiconductor chip 100 faces upward in the vertical direction (Z direction). The first semiconductor chip 100 may be mounted on the first adhesive layer AL1 so that the plurality of first input/output terminals 110 of the first semiconductor chip 100 face upward in the vertical direction (Z direction).

For example, in the process of stacking the first semiconductor chip 100 on the carrier substrate CR on which the first adhesive layer AL1 is applied, an external force that presses the first semiconductor chip 100 downward in the vertical direction (Z direction) may be applied relatively less. Accordingly, a phenomenon of fillet generation between the first semiconductor chip 100 and the first adhesive layer AL1 may be suppressed. For example, a phenomenon of the upper surface of the first adhesive layer AL1 becoming uneven may be suppressed.

Referring to FIGS. 9C to 9E, a plurality of lower first conductive posts CP1_L may be formed on the first semiconductor chip 100. For example, the plurality of lower first conductive posts CP1_L may be formed on the plurality of first input/output terminals 110 of the first semiconductor chip 100.

Referring to FIG. 9C, a lower seed layer SD1 may be formed on an upper portion of the resultant product of FIG. 9B. For example, the lower seed layer SD1 may be formed on a portion of the upper surface of the first adhesive layer AL1 that does not overlap with the first semiconductor chip 100 and on an upper surface and side surface of the first semiconductor chip 100.

For example, in the process of mounting the first semiconductor chip 100 on the first adhesive layer AL1, a phenomenon of fillet generation in the first adhesive layer AL1 is suppressed, and thus, the quality of the lower seed layer SD1 formed on the first adhesive layer AL1 may be improved.

Referring to FIG. 9D, after forming a first photoresist layer PR1 on the resultant product of FIG. 9C, a plurality of lower trenches TR1 may be formed. The plurality of lower trenches TR1 may be located on the plurality of first input/output terminals 110 of the first semiconductor chip 100. For example, a portion of the lower seed layer SD1 located above the plurality of first input/output terminals 110 may be exposed to the outside through the plurality of lower trenches TR1. In some embodiments, the plurality of lower trenches TR1 may have a horizontal width that decreases downwards in the vertical direction (Z direction).

Referring to FIG. 9E, a plurality of lower first conductive posts CP1_L may be formed by filling the plurality of lower trenches TR1 with a conductive material. The plurality of lower first conductive posts CP1_L may be located on the plurality of first input/output terminals 110 of the first semiconductor chip 100. Each of the plurality of lower first conductive posts CP1_L may have a narrower horizontal width closer to the first semiconductor chip 100. In some embodiments, a conductive material may be formed inside the plurality of lower trenches TR1 through an electrolytic plating process using the lower seed layer SD1 as a starting point.

Thereafter, the first photoresist layer PR1 and a portion of the lower seed layer SD1 may be removed. For example, a portion of the lower seed layer SD1 that is in contact with the first photoresist layer PR1 may be removed, and a portion of the lower seed layer SD1 that is in contact with the plurality of lower first conductive posts CP1_L may remain. A lower surface of the lower seed layer SD1 and the upper surface of the first semiconductor chip 100 may be coplanar.

Referring to FIG. 9F, a second semiconductor chip 200 may be offset-stacked on the first semiconductor chip 100. In some embodiments, the second semiconductor chip 200 may be offset-stacked on the first semiconductor chip 100 so that the plurality of second input/output terminals 210 located on an active surface 200_A of the second semiconductor chip 200 face upward in the vertical direction (Z direction).

In some embodiments, the second semiconductor chip 200 may be attached to the first semiconductor chip 100 via a second adhesive layer AL2. The second adhesive layer AL2 may be located on a lower surface of the second semiconductor chip 200. For example, an area of an upper surface of the second adhesive layer AL2 may be equal to an area of a lower surface of the second semiconductor chip 200. For example, after the second adhesive layer AL2 is applied to the lower surface of the second semiconductor chip 200, the second semiconductor chip 200 may be attached to the first semiconductor chip 100.

The second semiconductor chip 200 may be offset-stacked on the first semiconductor chip 100 in a state that the plurality of lower second conductive posts CP2_L are attached to the plurality of second input/output terminals 210 of the second semiconductor chip 200. For example, a separate seed layer may not exist between the plurality of lower second conductive posts CP2_L and the plurality of second input/output terminals 210.

For example, each of the plurality of lower second conductive posts CP2_L may be a conductive pillar. For example, a length of the plurality of lower second conductive posts CP2_L in the vertical direction (Z direction) may be in a range from about 5 μm to about 40 μm.

Referring to FIG. 9G, a first molding layer ML1 may be formed on the first adhesive layer AL1 to cover the first semiconductor chip 100, the second semiconductor chip 200, the plurality of lower first conductive posts CP1_L, and the plurality of lower second conductive posts CP2_L.

Thereafter, a portion of the first molding layer ML1 may be removed through a polishing process so that upper surfaces of the plurality of lower second conductive posts CP2_L are exposed to the outside. Accordingly, the upper surfaces of the plurality of lower first conductive posts CP1_L, the upper surfaces of the plurality of lower second conductive posts CP2_L, and the upper surface of the first molding layer ML1 may be coplanar.

Referring to FIG. 9H, a third adhesive layer AL3 may be applied on the first molding layer ML1. For example, the third adhesive layer AL3 may be applied so as to completely cover the upper surface of the first molding layer ML1. For example, an area of a lower surface of the third adhesive layer AL3 may be the same as an area of the upper surface of the first molding layer ML1. For example, a side surface of the third adhesive layer AL3 may be coplanar with a side surface of the first molding layer ML1.

In some embodiments, before applying the third adhesive layer AL3 onto the first molding layer ML1, the first insulating layer DL1 (see FIG. 8) may be formed on the first molding layer ML1. For example, after forming a first insulating layer on the first molding layer ML1 to completely cover the upper surface of the first molding layer ML1, the third adhesive layer AL3 may be applied on the first insulating layer to completely cover an upper surface of the first insulating layer. Through the first insulating layer, the adhesion between the first adhesive layer AL1 and the first molding layer ML1 may be improved.

Thereafter, a third semiconductor chip 300 may be placed on the third adhesive layer AL3. The third semiconductor chip 300 may be mounted on the third adhesive layer AL3 so that a plurality of third input/output terminals 310 located on an active surface 300_A of the third semiconductor chip 300 face upward in the vertical direction (Z direction). For example, an area of a lower surface of the third semiconductor chip 300 may be less than the area of an upper surface of the third adhesive layer AL3.

In some embodiments, the third semiconductor chip 300 may not overlap the plurality of lower first conductive posts CP1_L and the plurality of lower second conductive posts CP2_L in the vertical direction (Z direction).

In some embodiments, the third semiconductor chip 300 may be placed on the third adhesive layer AL3 in a state that a plurality of middle third conductive posts CP3_M are attached to the plurality of third input/output terminals 310 of the third semiconductor chip 300. For example, a separate seed layer may not exist between the plurality of middle third conductive posts CP3_M and the plurality of third input/output terminals 310 of the third semiconductor chip 300.

For example, in the process of stacking the third semiconductor chip 300 on the third adhesive layer AL3, because the third adhesive layer AL3 has a greater area than the third semiconductor chip 300, a phenomenon of fillet generation between the third semiconductor chip 300 and the third adhesive layer AL3 may be suppressed.

Referring to FIGS. 9I to 9L, a plurality of middle first conductive posts CP1_M, a plurality of middle second conductive posts CP2_M, and a middle seed layer SD_M may be formed.

Referring to FIG. 9I, a plurality of middle first trenches TR2_1 extending from the upper surface to the lower surface of the third adhesive layer AL3 may be formed. Some of the plurality of middle first trenches TR2_1 may be located on the plurality of lower first conductive posts CP1_L, and the remainder of the plurality of middle first trenches TR2_1 may be located on the plurality of lower second conductive posts CP2_L. In some embodiments, the plurality of middle first trenches TR2_1 may have a horizontal width that narrows downwards in the vertical direction. In some embodiments, the plurality of middle first trenches TR2_1 may be formed by using a laser drilling method.

Referring to FIG. 9J, a second photoresist layer PR2, which is located on the third adhesive layer AL3 and surrounds the third semiconductor chip 300, may be formed. Thereafter, a plurality of middle second trenches TR2_2 extending from an upper surface to a lower surface of the second photoresist layer PR2 may be formed. The plurality of middle second trenches TR2_2 may be in communication with the plurality of middle first trenches TR2_1. In some embodiments, the plurality of middle second trenches TR2_2 may have a horizontal width that decreases downwards in the vertical direction (Z direction).

The plurality of middle second trenches TR2_2 may be located on top of the plurality of middle first trenches TR2_1. For example, some of the plurality of middle second trenches TR2_2 may be located on top of the plurality of lower first conductive posts CP1_L, and the remainder of the plurality of middle second trenches TR2_2 may be located on top of the plurality of lower second conductive posts CP2_L.

Referring to FIG. 9K, a middle seed layer SD_M may be formed. The middle seed layer SD_M may be conformally formed on the upper surface of the second photoresist layer PR2, side surfaces of the plurality of middle first trenches TR2_1, and side surfaces of the plurality of middle second trenches TR2_2.

Referring to FIG. 9L, insides of the plurality of middle first trenches TR2_1 and the plurality of middle second trenches TR2_2 may be filled with a conductive material to form a plurality of middle first conductive posts CP1_M and a plurality of middle second conductive posts CP2_M.

For example, a plurality of middle first conductive posts CP1_M may be located on top of the plurality of lower first conductive posts CP1_L, and the plurality of middle second conductive posts CP2_M may be located on top of the plurality of lower second conductive posts CP2_L.

Afterwards, a portion of the second photoresist layer PR2 and the middle seed layer SD_M may be removed. For example, a portion of the middle seed layer SD_M that is in contact with the second photoresist layer PR2 may be removed, and a portion of the middle seed layer SD_M that is in contact with the third adhesive layer AL3 may remain. For example, the middle seed layer SD_M may be located between the plurality of middle first conductive posts CP1_M and the third adhesive layer AL3, and between a plurality of middle second conductive posts CP2_M and the third adhesive layer AL3.

In some embodiments, each of the plurality of middle first conductive posts CP1_M may be divided into a first portion CP1_M1 located within the middle first trench TR2_1 and a second portion CP1_M2 located within the middle second trench TR2_2. Each of the plurality of middle second conductive posts CP2_M may be divided into a first portion CP2_M1 located within the middle first trench TR2_1 and a second portion CP2_M2 located within the middle second trench TR2_2.

The following description is based on the plurality of middle first conductive posts CP1_M, but the plurality of middle first conductive posts CP1_M and the plurality of middle second conductive posts CP2_M may be substantially the same. In addition, the plurality of upper first conductive posts CP1_U, the plurality of upper second conductive posts CP2_U, and the plurality of upper third conductive posts CP3_U, which are described below, may also be substantially the same as the plurality of middle first conductive posts CP1_M.

In some embodiments, an inclination of a side surface of each of the plurality of middle first conductive posts CP1_M at the first portion CP1_M1 of each of the plurality of middle first conductive posts CP1_M and an inclination of a side surface of each of the plurality of middle first conductive posts CP1_M at the second portion CP1_M2 of each of the plurality of middle first conductive posts CP1_M may be different.

In some embodiments, a horizontal width of a lower surface of each of the plurality of middle first conductive posts CP1_M in the first portion CP1_M1 of each of the plurality of middle first conductive posts CP1_M may be different from a horizontal width of a lower surface of each of the plurality of middle first conductive posts CP1_M in the second portion CP1_M2 of each of the plurality of middle first conductive posts CP1_M.

Referring to FIG. 9M, a second molding layer ML2 may be formed on the third adhesive layer AL3 to cover the third semiconductor chip 300, the plurality of middle first conductive posts CP1_M, the plurality of middle second conductive posts CP2_M, and the plurality of middle third conductive posts CP3_M. In some embodiments, a side surface of the second molding layer ML2 may be coplanar with a side surface of the third adhesive layer AL3.

Thereafter, through a polishing process, a portion of the second molding layer ML2 may be removed so that an upper surfaces of the plurality of middle third conductive posts CP3_M are exposed to the outside. Accordingly, upper surfaces of the plurality of middle first conductive posts CP1_M, upper surfaces of the plurality of middle second conductive posts CP2_M, the upper surfaces of the plurality of middle third conductive posts CP3_M, and upper surface of the second molding layer ML2 may be coplanar.

The process of manufacturing a semiconductor package disclosed in FIGS. 9N to 9S may be substantially the same as the process of manufacturing a semiconductor package disclosed with reference to FIGS. 9H to 9N. For example, the process of manufacturing a semiconductor package disclosed in FIGS. 9N to 9S may be omitted or repeated depending on the number of semiconductor chips included in the semiconductor package.

In a semiconductor package manufacturing process in which the semiconductor package manufacturing process disclosed in FIGS. 9N to 9S is omitted, the plurality of middle first conductive posts CP1_M may be referred to as a plurality of upper first conductive posts CP1_U, the plurality of middle second conductive posts CP2_M may be referred to as a plurality of upper second conductive posts CP2_U, the plurality of middle third conductive posts CP3_M may be referred to as a plurality of third conductive posts CP3, and the middle seed layer SD_M may be referred to as an upper seed layer SD3. In addition, the plurality of middle first trenches TR2_1 may be referred to as a plurality of upper first trenches TR3_1, and the plurality of middle second trenches TR2_2 may be referred to as a plurality of upper second trenches TR3_2.

Referring to FIG. 9N, a fourth adhesive layer AL4 may be applied onto the second molding layer ML2. For example, the fourth adhesive layer AL4 may be applied to completely cover an upper surface of the second molding layer ML2. For example, a side surface of the fourth adhesive layer AL4 may be coplanar with a side surface of the second molding layer ML2.

In some embodiments, before applying the fourth adhesive layer AL4 on the second molding layer ML2, the second insulating layer DL2 (see FIG. 8) may be formed on the second molding layer ML2. Through a second insulating layer, the adhesion between the second adhesive layer AL2 and the second molding layer ML2 may be improved.

Thereafter, a fourth semiconductor chip 400 may be placed on the fourth adhesive layer AL4. The fourth semiconductor chip 400 may be mounted on the fourth adhesive layer AL4 so that a plurality of fourth input/output terminals 410 located on an active surface 400_A of the fourth semiconductor chip 400 face upward in the vertical direction (Z direction). For example, an area of a lower surface of the fourth semiconductor chip 400 may be less than an area of an upper surface of the fourth adhesive layer AL4.

In some embodiments, the fourth semiconductor chip 400 may not overlap with the plurality of middle first conductive posts CP1_M, the plurality of middle second conductive posts CP2_M, and the plurality of middle third conductive posts CP3_M in the vertical direction (Z direction).

In some embodiments, the fourth semiconductor chip 400 may be placed on the fourth adhesive layer AL4 in a state that the plurality of fourth conductive posts CP4 are attached to the plurality of fourth input/output terminals 410 of the fourth semiconductor chip 400. For example, a separate seed layer may not exist between the plurality of fourth conductive posts CP4 and the plurality of fourth input/output terminals 410 of the fourth semiconductor chip 400.

Referring to FIGS. 9O to 9R, a plurality of upper first conductive posts CP1_U, a plurality of upper second conductive posts CP2_U, and a plurality of upper third conductive posts CP3_U may be formed.

Referring to FIG. 9O, a plurality of upper first trenches TR3_1 extending from an upper surface to a lower surface of the fourth adhesive layer AL4 may be formed. Some of the plurality of upper first trenches TR3_1 may be located on the plurality of middle first conductive posts CP1_M, other some of the plurality of upper first trenches TR3_1 may be located on the plurality of middle second conductive posts CP2_M, and the remainder of the plurality of upper first trenches TR3_1 may be located on the plurality of middle third conductive posts CP3_M.

For example, the upper surfaces of the plurality of middle first conductive posts CP1_M, the upper surfaces of the plurality of middle second conductive posts CP2_M, and the upper surfaces of the plurality of middle third conductive posts CP3_M may be exposed to the outside by the plurality of upper first trenches TR3_1. For example, each of the plurality of upper first trenches TR3_1 may have a horizontal width that decreases downwards in the vertical direction (Z direction).

Referring to FIG. 9P, a third photoresist layer PR3 that is located on the fourth adhesive layer AL4 and surrounds the fourth semiconductor chip 400 may be formed. Thereafter, a plurality of upper second trenches TR3_2 extending from an upper surface to a lower surface of the third photoresist layer PR3 may be formed. The plurality of upper second trenches TR3_2 may be in communication with the plurality of upper first trenches TR3_1.

The plurality of upper second trenches TR3_2 may be located on top of the plurality of upper first trenches TR3_1. For example, some of the plurality of upper second trenches TR3_2 may be located on top of the plurality of middle first conductive posts CP1_M, other some of the plurality of upper second trenches TR3_2 may be located on top of the plurality of middle second conductive posts CP2_M, and the remainder of the plurality of upper second trenches TR3_2 may be located on top of the plurality of middle third conductive posts CP3_M. In some embodiments, each of the plurality of upper second trenches TR3_2 may have a horizontal width that decreases downwards in the vertical direction (Z direction).

Referring to FIG. 9Q, an upper seed layer SD3 may be formed. The upper seed layer SD3 may be conformally formed on the upper surface of the third photoresist layer PR3, side surfaces of the plurality of upper first trenches TR3_1, and side surfaces of the plurality of upper second trenches TR3_2.

Referring to FIG. 9R, insides of the plurality of upper first trenches TR3_1 and the plurality of upper second trenches TR3_2 may be filled with a conductive material to form a plurality of upper first conductive posts CP1_U, a plurality of upper second conductive posts CP2_U, and a plurality of upper third conductive posts CP3_U.

For example, the plurality of upper first conductive posts CP1_U may be located on upper surfaces of the plurality of middle first conductive posts CP1_M. A plurality of upper second conductive posts CP2_U may be located on top of a plurality of middle second conductive posts CP2_M. A plurality of upper third conductive posts CP3_U may be located on a plurality of middle third conductive posts CP3_M.

Thereafter, a portion of the third photoresist layer PR3 and the upper seed layer SD3 may be removed. For example, a portion of the upper seed layer SD3 that is in contact with the third photoresist layer PR3 may be removed, and a portion that is in contact with the fourth adhesive layer AL4 may remain.

For example, the upper seed layer SD3 may be located between the plurality of upper first conductive posts CP1_U and the fourth adhesive layer AL4, between the plurality of upper second conductive posts CP2_U and the fourth adhesive layer AL4, and between the plurality of upper third conductive posts CP3_U and the fourth adhesive layer AL4.

In some embodiments, each of the plurality of upper first conductive posts CP1_U may be divided into a first portion CP1_U1 located within the upper first trench TR3_1 and a second portion CP1_U2 located within the upper second trench TR3_2. Each of the plurality of upper second conductive posts CP2_U may be divided into a first portion CP2_U1 located within the upper first trench TR3_1 and a second portion CP2_U2 located within the upper second trench TR3_2. Each of the plurality of upper third conductive posts CP3_U may be divided into a first portion CP3_U1 located within the upper first trench TR3_1 and a second portion CP3_U2 located within the upper second trench TR3_2.

Referring to FIG. 9S, a third molding layer ML3 may be formed on the fourth adhesive layer AL4 to cover the fourth semiconductor chip 400, the plurality of upper first conductive posts CP1_U, the plurality of upper second conductive posts CP2_U, the plurality of upper third conductive posts CP3_U, and the plurality of fourth conductive posts CP4. In some embodiments, a side surface of the third molding layer ML3 may be coplanar with the side surface of the fourth adhesive layer AL4.

Thereafter, a portion of the third molding layer ML3 may be removed through a polishing process so that upper surfaces of the plurality of fourth conductive posts CP4 are exposed to the outside. Accordingly, upper surfaces of the plurality of upper first conductive posts CP1_U, upper surfaces of the plurality of upper second conductive posts CP2_U, upper surfaces of the plurality of upper third conductive posts CP3_U, upper surfaces of the plurality of fourth conductive posts CP4, and an upper surface of the third molding layer ML3 may be coplanar.

Referring to FIG. 9T, a redistribution structure RDL may be formed on the third molding layer ML3. A redistribution pattern RP of the redistribution structure RDL may be in contact with the plurality of first conductive posts CP1, the plurality of second conductive posts CP2, the plurality of third conductive posts CP3, and the plurality of fourth conductive posts CP4. Accordingly, the first semiconductor chip 100, the second semiconductor chip 200, the third semiconductor chip 300, and the fourth semiconductor chip 400 may be electrically connected to the redistribution structure RDL.

For example, external connection terminals CT may be attached to an upper surface of the redistribution structure RDL. In some embodiments, a redistribution via RV of the redistribution pattern RP of the redistribution structure RDL may become narrower in width downwards in the vertical direction (Z direction).

In some embodiments, a process of separating the first adhesive layer AL1 from the carrier substrate CR and removing the first adhesive layer AL1 through a polishing process may be additionally performed. For example, the polishing process may be performed until the lower surface of the first semiconductor chip 100 and the lower surface of the first molding layer ML1 are exposed. Accordingly, the lower surface of the first semiconductor chip 100 and the lower surface of the first molding layer ML1 may be exposed to the outside and may be coplanar with each other.

While the disclosure has been particularly shown and described with reference to embodiments thereof, it will be understood that various changes in form and details may be made therein without departing from the spirit and scope of the following claims.

What is claimed is:

1. A semiconductor package comprising:
a first semiconductor chip;
a plurality of lower first conductive posts on the first semiconductor chip;
a second semiconductor chip offset-stacked on the first semiconductor chip to be horizontally offset from the first semiconductor chip and horizontally spaced apart from the plurality of lower first conductive posts;
a second adhesive layer on a lower surface of the second semiconductor chip;
a plurality of lower second conductive posts on the second semiconductor chip;
a first molding layer around the first semiconductor chip, the plurality of lower first conductive posts, the second semiconductor chip, and the plurality of lower second conductive posts;
a third adhesive layer on an upper surface of the first molding layer;
a plurality of upper first conductive posts on the plurality of lower first conductive posts and penetrating the third adhesive layer;
a plurality of upper second conductive posts on the plurality of lower second conductive posts and penetrating the third adhesive layer;
a third semiconductor chip on the third adhesive layer and horizontally spaced apart from the plurality of upper first conductive posts and the plurality of upper second conductive posts;
a plurality of third conductive posts on the third semiconductor chip;
a second molding layer on the third adhesive layer and around the plurality of upper first conductive posts, the plurality of upper second conductive posts, the plurality of third conductive posts, and the third semiconductor chip; and
a redistribution structure on the second molding layer and contacting the plurality of upper first conductive posts, the plurality of upper second conductive posts, and the plurality of third conductive posts.

2. The semiconductor package of claim 1, wherein a side surface of the first molding layer, a side surface of the third adhesive layer, and a side surface of the second molding layer are coplanar,
wherein an area of an upper surface of the second adhesive layer is equal to an area of the lower surface of the second semiconductor chip, and
wherein an area of an upper surface of the third adhesive layer is greater than an area of a lower surface of the third semiconductor chip.

3. The semiconductor package of claim 1, wherein thicknesses of the second adhesive layer and the third adhesive layer in a vertical direction are in a range of about 5 μm to about 40 μm.

4. The semiconductor package of claim 1, wherein horizontal widths of the plurality of lower first conductive posts are greater than horizontal widths of the plurality of lower second conductive posts.

5. The semiconductor package of claim 1, wherein the plurality of upper first conductive posts comprise first portions and second portions,
wherein the third adhesive layer is disposed around the first portions,
wherein the second molding layer is disposed around the second portions, and
wherein horizontal widths of the first portions are different from horizontal widths of the second portions.

6. The semiconductor package of claim 1, further comprising:
a lower seed layer; and
an upper seed layer,
wherein the lower seed layer is on lower surfaces of the plurality of lower first conductive posts,
wherein a portion of the upper seed layer is between the plurality of upper first conductive posts and the third adhesive layer, and between the plurality of upper first conductive posts and the plurality of lower first conductive posts, and
wherein another portion of the upper seed layer is between the plurality of upper second conductive posts and the third adhesive layer, and between the plurality of upper second conductive posts and the plurality of lower second conductive posts.

7. The semiconductor package of claim 1, wherein upper surfaces of the plurality of lower first conductive posts, upper surfaces of the plurality of lower second conductive posts, and the upper surface of the first molding layer are coplanar.

8. The semiconductor package of claim 1, wherein upper surfaces of the plurality of upper first conductive posts, upper surfaces of the plurality of upper second conductive posts, upper surfaces of the third conductive posts, and an upper surface of the second molding layer are coplanar.

9. The semiconductor package of claim 8, wherein the redistribution structure comprises:
a redistribution pattern comprising a redistribution line and a redistribution via extending in a vertical direction from the redistribution line; and
a redistribution insulation layer around the redistribution pattern, and
wherein a horizontal width of the redistribution via decreases towards the second molding layer.

10. The semiconductor package of claim 1, further comprising:
a first insulating layer between the third adhesive layer and the first molding layer,
wherein a side surface of the first insulating layer is coplanar with a side surface of the first molding layer,
wherein the plurality of upper first conductive posts penetrate through the first insulating layer and the third adhesive layer and are in contact with the plurality of lower first conductive posts, and
wherein the plurality of upper second conductive posts penetrate through the first insulating layer and the third adhesive layer and are in contact with the plurality of lower second conductive posts.

11. A semiconductor package comprising:
a first semiconductor chip;
a second semiconductor chip offset-stacked on the first semiconductor chip to be horizontally offset from the first semiconductor ship;
a second adhesive layer on a lower surface of the second semiconductor chip;
a first molding layer on the first semiconductor chip, the second semiconductor chip, and the second adhesive layer;
a third adhesive layer on an upper surface of the first molding layer;
a third semiconductor chip on the third adhesive layer and horizontally offset from the second semiconductor chip;
a second molding layer on the third adhesive layer and the third semiconductor chip;
a fourth adhesive layer on the second molding layer;
a fourth semiconductor chip on the fourth adhesive layer and horizontally offset from the third semiconductor chip;
a third molding layer on the fourth adhesive layer and the fourth semiconductor chip;
a redistribution structure on the third molding layer;
a plurality of first conductive posts extending from the first semiconductor chip to the redistribution structure and horizontally spaced apart from the second semiconductor chip, the third semiconductor chip, and the fourth semiconductor chip;
a plurality of second conductive posts extending from the second semiconductor chip to the redistribution structure and horizontally spaced apart from the third semiconductor chip and the fourth semiconductor chip;
a plurality of third conductive posts extending from the third semiconductor chip to the redistribution structure and horizontally spaced apart from the fourth semiconductor chip; and
a plurality of fourth conductive posts extending from the fourth semiconductor chip to the redistribution structure.

12. The semiconductor package of claim 11, wherein a side surface of the first molding layer, a side surface of the third adhesive layer, a side surface of the second molding layer, a side surface of the fourth adhesive layer, and a side surface of the third molding layer are coplanar,
wherein the plurality of first conductive posts comprise lower first conductive posts penetrating the first molding layer, middle first conductive posts penetrating the third adhesive layer and the second molding layer, and upper first conductive posts penetrating the fourth adhesive layer and the third molding layer,
wherein the middle first conductive posts comprise first portions penetrating the third adhesive layer and second portions penetrating the second molding layer,
wherein the upper first conductive posts comprise first portions penetrating the fourth adhesive layer and second portions penetrating the third molding layer,
wherein horizontal widths at lower surfaces of the second portions of the middle first conductive posts are different from horizontal widths at upper surfaces of the first portions of the middle first conductive posts, and
wherein horizontal widths at lower surfaces of the second portions of the upper first conductive posts are different from horizontal widths at upper surfaces of the first portions of the upper first conductive posts.

13. The semiconductor package of claim 12, wherein horizontal widths of the lower first conductive posts decrease towards the first semiconductor chip,
wherein horizontal widths of the first portions and the second portions of the middle first conductive posts decrease towards the first semiconductor chip, and
wherein horizontal widths of the first portions and the second portions of the upper first conductive posts decrease towards the first semiconductor chip.

14. The semiconductor package of claim 13, wherein inclinations of side surfaces of the first portions of the middle first conductive posts are different from inclinations of side surfaces of the second portions of the middle first conductive posts, and
wherein inclinations of side surfaces of the first portions of the upper first conductive posts are different from inclinations of side surfaces of the second portions of the upper first conductive posts.

15. The semiconductor package of claim 12, further comprising:
a lower seed layer;
a middle seed layer; and
an upper seed layer,
wherein the lower seed layer is between the lower first conductive posts and the first semiconductor chip,
wherein the middle seed layer is between the middle first conductive posts and the lower first conductive posts, and between the middle first conductive posts and the third adhesive layer, and
wherein the upper seed layer is between the upper first conductive posts and the middle first conductive posts, and between the upper first conductive posts and the fourth adhesive layer.

16. A method of manufacturing a semiconductor package, the method comprising:
disposing a first semiconductor chip on a first adhesive layer after applying the first adhesive layer on a carrier substrate;
forming a plurality of lower first conductive posts on the first semiconductor chip;
offset-stacking a second semiconductor chip on the first semiconductor chip to be horizontally offset from the first semiconductor chip and horizontally spaced apart from the plurality of lower first conductive posts, wherein the second semiconductor chip comprises a plurality of lower second conductive posts on an upper surface thereof;
forming a first molding layer on the first adhesive layer, the plurality of lower first conductive posts, the plurality of lower second conductive posts, and the second semiconductor chip;
disposing a third semiconductor chip on a third adhesive layer after applying the third adhesive layer on the first molding layer, the third semiconductor chip comprising a plurality of third conductive posts on an upper surface thereof;
forming a plurality of upper first conductive posts on the plurality of lower first conductive posts and a plurality of upper second conductive posts on the plurality of lower second conductive posts;
forming a second molding layer on the third adhesive layer, the plurality of upper first conductive posts, the plurality of upper second conductive posts, the plurality of third conductive posts, and the third semiconductor chip; and
forming a redistribution structure on the second molding layer.

17. The method of claim 16, further comprising:
before applying the third adhesive layer, forming a first insulating layer on the first molding layer.

18. The method of claim 16, wherein the forming of the upper first conductive posts and the upper second conductive posts further comprises:
forming a plurality of upper first trenches on the lower first conductive posts and the lower second conductive posts, the plurality of upper first trenches extending from an upper surface to a lower surface of the third adhesive layer;
forming a second photoresist layer on the third adhesive layer around the third semiconductor chip; and
forming a plurality of upper second trenches extending from an upper surface to a lower surface of the second photoresist layer and abutting the plurality of upper first trenches.

19. The method of claim 18, wherein the forming the upper first conductive posts and the upper second conductive posts further comprises:
forming an upper seed layer on the upper surface of the second photoresist layer, side surfaces of the plurality of upper first trenches, and side surfaces of the plurality of upper second trenches, after forming the plurality of upper second trenches.

20. The method of claim 16, wherein the offset-stacking of the second semiconductor chip on the first semiconductor chip further comprises applying a second adhesive layer on a lower surface of the second semiconductor chip,
wherein an area of a lower surface of the first semiconductor chip is less than an area of an upper surface of the first adhesive layer,
wherein an area of a lower surface of the second semiconductor chip is equal to an area of an upper surface of the second adhesive layer, and
wherein an area of a lower surface of the third semiconductor chip is less than an area of an upper surface of the third adhesive layer.
